(19) United States
(12) Patent Application Publication
(10) Pub. No.: US 2022/0239068 A1
(43) Pub. Date: Jul. 28, 2022

(54) III-NITRIDE-BASED VERTICAL CAVITY SURFACE EMITTING LASER (VCSEL) CONFIGURATIONS

(71) Applicant: The Regents of the University of California, Oakland, CA (US)

(72) Inventors: Jared Kearns, Goleta, CA (US); Daniel A. Cohen, Santa Barbara, CA (US); Joonho Back, Goleta, CA (US); Nathan Palmquist, Santa Barbara, CA (US); Tal Margalith, Santa Barbara, CA (US); Steven P. DenBaars, Goleta, CA (US); Shuji Nakamura, Santa Barbara, CA (US)

(73) Assignee: The Regents of the University of California, Oakland, CA (US)

(21) Appl. No.: 17/613,659

(22) PCT Filed: May 28, 2020
(86) PCT No.: PCT/US20/34955

§ 371 Date: Nov. 23, 2021

Related U.S. Application Data
(60) Provisional application No. 62/866,183, filed on Jun. 25, 2019.
(60) Provisional application No. 62/854,046, filed on May 29, 2019.

(51) Int. Cl. H01S 5/183; H01S 5/34; H01S 5/343

(52) U.S. Cl. CPC H01S 5/18361; H01S 2304/04; H01S 5/34333; H01S 5/3416

(57) ABSTRACT

Vertical Cavity Surface Emitting Laser (VCSEL) configurations are disclosed. In a first example, the VCSEL includes a III-Nitride active region between a p-type III-Nitride layer and an n-type III-Nitride layer; and a curved minor on or above the p-type III-Nitride layer. The curved mirror can be formed in a III-Nitride layer or a Transparent Oxide (TO) material and enables the formation of a long VCSEL cavity that improves VCSEL lifetime, VCSEL output power, VCSEL power efficiency and VCSEL reliability. In a second example, the VCSEL has an active region with a high indium content. In a third example, the VCSEL is transparent.

### CROSS REFERENCE TO RELATED APPLICATIONS

This application claims the benefit under 35 U.S.C. Section 119(e) of the following co-pending and commonly-assigned applications:

U.S. Provisional Patent Application No. 62/854,046 filed May 29, 2019, by Jared Kearns, Daniel Cohen, Joonho Back, and Shuji Nakamura, entitled “III-NITRIDE-BASED VERTICAL CAVITY SURFACE EMITTING LASER(VCSEL) WITH CURVED MIRROR ON P-SIDE OF THE APERTURE” Attorney's Docket No. 30794.728-US-P1 (2019-934); and

U.S. Provisional Patent Application No. 62/866,183, filed Jun. 25, 2019, by Nathan Palmquist, Jared Kearns, and Shuji Nakamura, entitled “III-NITRIDE VERTICAL-CAVITY SURFACE EMITTING LASERS WITH A HIGH INDIUM CONTENT ACTIVE REGION” Attorney's Docket No. 30794.730-US-P1 (2019-935)

all of which applications are incorporated by reference herein.

### BACKGROUND OF THE INVENTION

### 1. Field of the Invention

The present invention relates to Vertical Cavity Surface Emitting Lasers (VCSELs) and methods of making the same.

### 2. Description of the Related Art

(Note: This application references a number of different references as indicated throughout the specification by one or more reference numbers in brackets, e.g., [x]. A list of these different publications ordered according to these reference numbers can be found below in the section entitled “References.” Each of these publications is incorporated by reference herein.

VCSELs can be used for sensing, lighting, communications and other applications. What is needed are VCSELs having improved lifetime, efficiency, output power and reliability. The present invention satisfies this need.

### SUMMARY OF THE INVENTION

An embodiment of the present invention concerns the placement of a curved mirror on or above the p-layer for a III-nitride based VCSEL. Using a curved mirror allows for the use of longer cavity devices with lower diffraction loss. Low absorption loss operation with a curved mirror is made possible by using a tunnel junction or oxide layer above the p-GaN to allow the majority of the cavity to be formed from a low loss material.

The use of high indium content quantum dots (QDs) has been shown to be a viable way to achieve long-wavelength emission. One or more embodiments of the present invention comprise a III-N VCSEL with an epitaxially grown active region comprising high In content dots or dashes originating from coalesced dots.

The present disclosure further describes a fully transparent VCSEL for use in transparent displays, including near-eye displays for augmented reality (AR) and mixed reality (MR) applications. In one or more examples, the VCSEL comprises epitaxial layers, contacts, mirrors, and a substrate all designed to maximize the transparency of the VCSEL.

Examples of embodiments described herein include, but are not limited to, the following.

1. A device, comprising:
a III-Nitride based Vertical Cavity Surface Emitting Laser (VCSEL), comprising:

a III-Nitride active region between a p-type III-Nitride layer and an n-type III-Nitride layer; and

a curved mirror on or above the p-type III-Nitride layer such that the p-type III-Nitride layer is between the III-Nitride active region and the curved mirror.

2. The device of claim 1, wherein the VCSEL further comprises:

one or more tunnel junction layers on the p-type III-Nitride layer, wherein the curved mirror is formed on or above the tunnel-junction layers such that the tunnel-junction layers are between the curved mirror and the p-type III-Nitride layer.

3. The device of claim 2, wherein the VCSEL further comprises:

a second n-type III-Nitride region on or above the tunnel junction layers, wherein the curved mirror includes the second n-type III-Nitride region and second the n-type III-Nitride region has a curvature forming the curved mirror.

4. The device of clause 3, wherein the second n-type III-Nitride region has an etched surface having the curvature.

5. The device of clause 4, wherein the second n-type III-Nitride region comprises n-type gallium nitride or unintentionally doped gallium nitride.

6. The device of clause 1, wherein:

the VCSEL further comprises a flat distributed bragg reflector (DBR) mirror,

the curved mirror comprises a curved DBR mirror,

the III-Nitride active region is between the flat DBR mirror and the curved DBR mirror, and

the flat DBR minor and the curved DBR minor define a cavity of the VCSEL.

7. The device of the clause 6, wherein a total cavity length of the cavity is more than 8 micrometers.

8. The device of clause 6, wherein more than 50% of the VCSEL's cavity is composed of, comprises, or consists essentially of epitaxially grown GaN, unintentionally doped (UID) GaN or n-type GaN.

9. The device of the clause 1, wherein all of the III-Nitride layers of the VCSEL are grown epitaxially by metal organic chemical vapor deposition (MOCVD).

10. The device of any of clause 1, wherein:

the VCSEL further comprises a flat III-nitride layer and a first Distributed Bragg Reflector (DBR) on the flat III-nitride layer,

the active region is between the flat III-nitride layer and the curved mirror,

the curved mirror includes a second Distributed Bragg Reflector (DBR), and

a distance between the second DBR and the active region is shorter than the distance between first DBR and the active region.

11. The device of clause 1, wherein:

the VCSEL further comprises an unintentionally doped gallium nitride (UID GaN) layer on the n-type III-Nitride layer, wherein the UID GaN is thick (thicker than the n-type III-Nitride layer),

the n-type III-Nitride layer comprises n-type gallium nitride (n-GaN),

the UID GaN is etched to expose a surface of the n-GaN, and

a metal contact or Ohmic contact material is deposited on the exposed surface of the n-GaN.

12. A method of fabricating the VCSEL of any of the preceding clauses, comprising:

growing the VCSEL structure on a gallium nitride (GaN) substrate; and

removing the GaN substrate so that the GaN substrate can be re-used more than 3 times.

13. A device, comprising:

a III-Nitride based Vertical Cavity Surface Emitting Laser (VCSEL), comprising a curved mirror formed on or in a Transparent Oxide (TO) material.

14. The device of clause 13, wherein the transparent Oxide (TO) material comprises ZnO, Ga₂O₃, or Al₂O₃.

15. The device of clause 13, wherein the VCSEL further comprises:

a III-Nitride active region between a p-type III-Nitride layer and an n-type III-Nitride layer; and

the transparent Oxide (TO) material on or above the p-type III-Nitride layer such that the p-type III-Nitride layer is between the III-Nitride active region and the Transparent Oxide (TO) material having a curved surface forming the curved mirror.

16. The device of clause 15, further comprising:

a III-Nitride tunnel junction on the p-type III-Nitride layer, wherein the transparent Oxide (TO) material is grown on or above the IIII-Nitride tunnel junction such that the III-Nitride tunnel junction is between the curved mirror and the p-type III-Nitride layer.

17. The device of clause 13, wherein:

the VCSEL further comprises a flat DBR mirror,

the curved mirror comprises a curved DBR mirror,

the flat DBR mirror and the curved DBR mirror define a cavity of the VCSEL.

18. The device of clause 17, wherein a total cavity length of the VCSEL's cavity is more than 8 micrometers.

19. The device of any clause 13, wherein all of the III-Nitride layers of the VCSEL are grown epitaxially by metal organic chemical vapor deposition (MOCVD).

20. The device of clause 13, wherein a thickness of the transparent oxide material is more than 5 micrometers.

21. A method of fabricating the VCSEL of clause 13, comprising

growing the VCSEL structure on a gallium nitride substrate; and

removing the GaN substrate so that the GaN substrate can be re-used as a growth substrate more than 3 times.

22. The VCSEL of clause 15, further comprising a flat distributed bragg reflector (DBR) mirror, wherein the active region is in a cavity between the flat DBR mirror and the curved mirror comprising a curved DBR mirror, and:

the active region emits electromagnetic radiation in response to:
a voltage applied between the p-type III-Nitride layer and the n-type III-Nitride region, and/or
one or more recombinations (in the active region) each comprising recombination of a hole (from the p-type III-Nitride layer) with an electron (from the n-type III-Nitride layer), and

the electromagnetic radiation is reflected between the curved DBR mirror and the flat DBR mirror so as to optically pump the III-Nitride active region and generate stimulated emission of the electromagnetic radiation having an intensity such that gain of the electromagnetic radiation occurs and the VCSEL lases and emits the electromagnetic radiation comprising coherent electromagnetic radiation through the flat mirror and/or the curved mirror.

23. The VCSEL of clause 22, further comprising an aperture in the cavity, wherein the curved mirror has a curvature focusing the electromagnetic radiation within (or at least 90% within) the aperture.

24. The VCSEL of clause 23, wherein:

current flows in response to the voltage, and

the aperture is a current aperture in the p-type III-Nitride layer and the active region, the VCSEL further comprises an implanted region or current barrier around the current aperture preventing flow of the current in the implanted region or the current barrier and diverting flow of the current to the current aperture.

25. The VCSEL of clauses 22, wherein the curved mirror has a curvature focusing the electromagnetic radiation so that, when a length of the cavity varies from its designed length due to thermal effects, the VCSEL continues to lase when an otherwise similar VCSEL having a flat mirror instead of the curved mirror would cease lasing under the same conditions.

26. A device, comprising:

a III-Nitride Vertical Cavity Surface Emitting Laser (VCSEL) including:

an n-type III-Nitride region;

a p-type III-Nitride region;

a III-nitride active region between the n-type III-Nitride region and the p-type III-Nitride region, wherein the III-Nitride active region comprises partially or fully relaxed high indium content III-Nitride quantum dots having an indium content of more than 30%.

27. The device of clause 26, further comprising

a first contact to the n-type III-Nitride region; and

a second contact to the p-type III-Nitride region or to a second n-type III-Nitride region on the p-type III-Nitride region, wherein the first contact and the second contact are on the same side of the III-Nitride VCSEL.

28. The device of clause 26, wherein the III-Nitride active region, the n-type III-Nitride region, and the p-type III-Nitride region are grown on a semipolar or nonpolar orientation GaN substrate.

29. The device of clause 26, wherein the III-Nitride VCSEL comprises a cavity and more than 50% of the cavity comprises a transparent oxide (TO) material.

30. The device of clause 29, wherein:

the transparent oxide material is on or above the n-type III-Nitride region comprising gallium nitride (GaN),

the III-Nitride VCSEL further includes an antireflection coating between the transparent oxide material and the GaN so as to suppress unwanted reflections at an interface between the GaN and the transparent oxide material.

31. The device of clause 26, further comprising a current spreading layer including:

a transparent conductive oxide (TCO) on or above the n-type III-nitride region, or

a second n-type III-Nitride region including n-GaN and n⁺⁺-GaN which form a tunnel junction with the p-type III-Nitride region comprising p⁺⁺-GaN.

32. The device of clause 26, further comprising a current spreading layer including a p⁺⁺-AlGaN layer having a thickness of 1-5 nm, wherein the p⁺⁺-AlGaN layer is on the p-type III-Nitride region.

33. The device of clause 26, wherein the VCSEL includes:

a p-n junction comprising the p-type III-Nitride region, the n-type III-nitride region, and the III-Nitride active region between the p-type III-Nitride region and the n-type III-nitride region;

the p-type III-Nitride layer comprising p-type GaN;

the n-type III-Nitride layer comprising n-type GaN; and

a transparent oxide including a curved mirror located on the n-type GaN side of the p-n junction, and wherein no curved mirror is located on the p-type GaN side of the p-n junction.

34. The device of clause 26, wherein the p-type III-Nitride region including p-GaN is grown below the III-Nitride active region.

35. The device of clause 26, wherein the p-type III-Nitride region including p-GaN is activated after the removal of a substrate upon which the III-Nitride VCSEL is grown.

36. The device of clause 26, wherein a growth temperature of the n-type III-Nitride region including n-type GaN is lower than 800 degrees Celsius.

37. The device of clause 26, wherein the III-Nitride VCSEL further includes:

a second n-type III-nitride region on the p-type III-Nitride region, the second n-type III-Nitride region forming a tunnel junction with the p-type III-Nitride region.

38. A method of making a device, comprising:

growing an epitaxial structure for a III-Nitride Vertical Cavity Surface Emitting Laser (VCSEL) including:

growing an n-type III-Nitride layer at a growth temperature lower than 800 degrees Celsius;

growing a p-type III-Nitride layer; and

growing a III-nitride active region; and wherein:

the III-Nitride active region is between the n-type III-Nitride layer and the p-type III-Nitride layer.

39. The method of clause 38, wherein:

the epitaxial structure is grown on a substrate, and

the p-type III-Nitride layer is grown prior to (or below) the III-Nitride active region so that the p-type III-Nitride layer is between the substrate and the III-Nitride active region.

40. The method of clause 38, wherein the p-type III-Nitride layer including p-GaN is activated after the removal of the substrate upon which the epitaxial structure is grown.

41. The method of any of the clauses 38, further comprising:

forming a first contact to the n-type III-Nitride layer; and

forming a second contact to the p-type III-Nitride layer or to a second n-type III-Nitride layer on the p-type III-Nitride layer, wherein the first contact and the second contact are on a same side of the III-Nitride VCSEL.

42. A VCSEL fabricated using the method of clause 38.

43. The method of clause 38 wherein the III-Nitride active region comprises partially or fully relaxed high indium content III-Nitride quantum dots having an indium content of more than 30%.

44. The method of clause 43, wherein the III-Nitride VCSEL further comprises

a current spreading layer including:
a transparent conductive oxide (TCO) on or above the n-type III-nitride layer, or
a second n-type III-Nitride region including a tunnel junction with the p-type III-Nitride region, or
a p-type AlGaN layer on the p-type III-Nitride layer and confining a two dimensional hole gas.

45. The method of clause 38, wherein the VCSEL further comprises:

a flat mirror, wherein the active region is in a cavity between the flat mirror and a curved mirror comprising a curved mirror on an n-type side of the VCSEL, and:

the active region emitting electromagnetic radiation in response to:
a voltage applied between the p-type III-Nitride layer and the n-type III-Nitride region, and/or
one or more recombinations (in the active region) each comprising recombination of a hole (from the p-type III-Nitride layer) with an electron (from the n-type III-Nitride layer); and

a transparent oxide on the n-type III-Nitride layer.

46. A device, comprising:

a Vertical Cavity Surface Emitting Laser (VCSEL) wherein all layers of the VCSEL are transparent to visible wavelengths except for:

an emitting layer, and

cavity mirrors defining a lasing cavity of the VCSEL.

47. The device of clause 46, further comprising a submount and a bonding material bonding the submount to the VCSEL, wherein the submount and the bonding material are transparent to the visible wavelengths.

48. The device of clause 47, wherein the VCSEL emits light through a surface that is not bonded to the submount.

49. The device of clause 47, wherein the VCSEL emits light through a surface that is bonded to the submount.

50. The device of clause 46, wherein the cavity mirrors are dielectric mirrors.

51. The device of clause 46, wherein the cavity mirrors are epitaxial mirrors, dielectric mirrors, or a combination thereof.

52. A device, comprising:
one or more Vertical Cavity Surface Emitting Laser (VCSEL)s, the VCSELs each including:

an epitaxial structure including a III-nitride active region between a first III-nitride n-type layer and a III-nitride p-type layer;

a first mirror and a second mirror on opposite sides of the epitaxial structure;

a first contact to the III-nitride n-type layer, the first contact comprising a first transparent conductive oxide; and

a second contact to the III-nitride p-type layer, the second contact comprising a second transparent conductive oxide; and wherein:

at least a portion of the epitaxial structure is between the first contact and the second contact,

electromagnetic radiation is emitted from the active region in response to a voltage applied between the first contact and the second contact,

the electromagnetic radiation is outputted from the VCSEL through the first mirror or the second mirror, and

a surface on which the VCSEL is mounted is visible through the first contact, the second contact, and the portion of epitaxial structure between the first contact and the second contact.

53. The device of clause 52, wherein the first mirror and the second mirror each comprise a distributed bragg reflector comprising epitaxial and/or dielectric material.

54. The device of clauses 52, wherein:

the first contact is positioned around a perimeter of the first mirror or includes sections on opposite sides of the first mirror; and

the second contact is on all exposed surfaces of the second mirror.

55. The device of clause 52, wherein the second mirror is embedded in the second contact.

56. The device of clause 52, wherein the first transparent conductive oxide and the second transparent conductive oxide each independently comprise indium tin oxide, or zinc and oxygen.

57. The device of clause 52, further comprising:

a second III-nitride n-type layer forming a tunnel junction with the III-nitride p-type layer, and

the second contact forming a contact to the tunnel junction.

58. The device of clause 52, further comprising a submount and a bonding material bonding the submount to the VCSEL, wherein the submount and the bonding material are transparent or include portions that are transparent to visible wavelengths such that a surface on which the submount is mounted is visible through the first contact, the second contact, the submount or portions of the submount, and the bonding material.

59. The device of clause 58, wherein the bonding material bonds the second contact to the submount.

60. The device of the clause 58, further comprising a third transparent conductive oxide between the bonding material and the submount, wherein the third transparent conductive oxide includes electrical traces for electrically contacting with the VCSEL and/or comprises electrically conductive paths used in a display attached to or comprising the VCSEL.

61. The device of clause 58, wherein the bonding material comprises a conductive adhesive.

62. The device of clause 58, wherein the bonding material includes metal particles embedded in a polymer matrix.

63. The device of clause 58, wherein the submount comprises sapphire, glass, or polymer.

64. The device of clause 58, further comprising a current aperture defined in the epitaxial layers, the current aperture defined using ion implanted material, a dielectric or air-gap aperture, a buried tunnel junction, or a combination thereof.

65. A display comprising an array of the VCSELs of clause 58, wherein the surface on which the VCSELs are mounted is a display screen electronically displaying text and/or graphics that is readable or viewable by naked eye through the first contact, the second contact, the portion of epitaxial material between the first contact and the second contact, the bonding material, and/or the submount.

66. A display comprising an array of the VCSELs of clause 58, wherein each of the VCSELs comprise a pixel in the display, each of the VCSELs are on or above a surface, and more than 50% of the intensity of each of red, green, and blue light emitted from the surface is transmitted through the combined thickness of the first contact, the portion of the epitaxial structure, and the second contact.

67. A display comprising an array of the VCSELs of clause 58, wherein each of the VCSELs comprise a pixel in the display, each of the VCSELs are on or above a surface, and more than 50% of the intensity of each of red, green, and blue light emitted from the surface is transmitted through the submount, the bonding material, the second contact, the portion of the epitaxial structure, and the first contact.

68. The display of clause 65, wherein the display comprises a virtual reality or augmented reality or mixed reality display.

### BRIEF DESCRIPTION OF THE DRAWINGS

Referring now to the drawings in which like reference numbers represent corresponding parts throughout:

FIG. 1. General processing of lens formation using thermal reflow.

FIG. 2. General device structure using a thick unintentional doping (UID)-GaN as a significant portion of the cavity thickness.

FIG. 3. General device structure using a transparent oxide as a significant portion of the cavity thickness.

FIG. 4. Flowchart illustrating a method of making a VCSEL according to a first example.

FIG. 5. General processing of lens formation using thermal reflow according to another example.

FIG. 6. The epitaxial structures for three different current spreading designs (a-c): with a tunnel junction (a), using a transparent conductive oxide (TCO) (b), and using a hole gas at the AlGaN/GaN interface (c). FIG. 6(d) shows the epitaxial structure if an electron blocking layer is required.

FIG. 7. Device structure with: current spreading layers comprised of (a) TJ/n-GaN, (b) TCO, (c) thin layer of AlGaN/n-GaN. (d) Device structure with electron blocking layer (EBL) in between active region and p-GaN.

FIG. 8. General device structure using a buried tunnel junction current aperture.

FIG. 9. Flowchart illustrating a method of making a device according to a second example.

FIG. 10. Schematic of the UC Santa Barbara VCSEL structure (right) and scanning electron microscope (SEM) image of a VCSEL showing a focused ion beam (FIB) cross-section (left) [8].

FIG. 11. Schematic of a third-generation UCSB VCSEL device incorporating a buried tunnel junction (BTJ) for current aperturing. The BTJ in this device was grown using MOCVD for both p++ and n++ layers, with a growth interrupt.

FIG. 12. Schematic of a transparent VCSEL. Metal contact layers have been replaced by transparent conductive oxide. The sapphire submount is also transparent.

FIG. 13. Schematic top view of a display comprising VCSELs according to one or more examples described herein.

FIG. 14. Flowchart illustrating a method of making a VCSEL according to a third example.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

I: III-Nitride-Based Vertical Cavity Surface Emitting Laser (VCSEL) with Curved Mirror on P-Side of the Aperture

### A. INTRODUCTION

Section I discloses a III-Nitride vertical-cavity surface-emitting laser (VCSEL) which incorporates a curved mirror formed above the p-side of the device. The use of a curved mirror allows for the following.

1. The use of a long cavity without suffering from excessive diffraction loss. With two planar mirrors defining the cavity, the loss due to diffraction increases with the cavity length [1,2]. When using a curved mirror, the reflected light can be focused back into the center of the aperture, minimizing diffraction loss.

2. Better thermal management, increasing the lifetime, output power, efficiency and reliability of the devices. High efficiency VCSEL operation needs the gain spectrum to be well aligned to the cavity mode. As the cavity length increases the mode spacing decreases. This means that as the gain spectrum shifts with temperature, there is an efficient number of cavity modes to ensure good mode overlap with the gain spectrum. Thus, as the drive current is increased and the gain spectrum shifts, the effects leading to thermal rollover of the output power are significantly reduced using the long cavity. Additionally, the tight cavity mode spacing allows for a greater tolerance of the cavity length and the location of the active layer. For short cavity devices, the cavity length and the location of the active layer must be precisely designed to have a cavity mode overlapping with the gain spectrum. If the cavity length and the location of the active layer varies from the designed length and the location, then the overlapping between the cavity mode and the gain spectrum is minimized in the short cavity. As a result, modal gain becomes smaller than the threshold gain, and no lasing happens. On the other hand, variations in the length of a long cavity and the location of the active layer does not matter in the long cavity VCSEL. There are so many cavity modes with a tight mode spacing in the long cavity. Even if the gain spectrum varies due to the fluctuation of the cavity length and location active layer, the overlapping between the cavity mode and the gain spectrum is good due to a tight mode spacing. Thus, having a long cavity design can increase the yield during device growth and fabrication.

3. Promotion of single mode operation, which is important in many applications [3,4].

Hamaguchi et al. have experimentally shown many of these advantages for a III-Nitride based VCSEL where a curved mirror was thrilled on the back side of the substrate[1]. While this design has shown good results and doesn't require substrate removal, it has several disadvantages. First of all, the substrate must be thinned to reduce the absorption loss in the cavity, which can be a difficult process to control and may damage the wafer.

In our invention, an advantage of forming the curved mirror on the top side of the epitaxially grown surface is eliminating the substrate thinning. For blue and green VCSELs, the long cavity length should be 8-30 microns considering the number of cavity modes and the mode spacing. It is difficult to uniformly thin the substrate from an initial thickness of 300-400 microns to 10-30 microns. It is easy to grow 10-30 micron thickness epitaxially and uniformly by using MOCVD and other techniques. This allows better control of the cavity thickness uniformity, and much cheaper in the view of the costs without substrate thinning.

Not having to thin the substrate reduces processing time, complexity, and costs. Thinned substrates become susceptible to breaking and therefore retaining the full substrate or bonding to a submount makes the samples more robust. The p-side curved mirror is also compatible with a standard dual dielectric mirror design fabrication through epitaxial lateral overgrowth or substrate removal [5,6].

Several embodiments of the present invention are presented below after a discussion of the methods for developing a curved mirror above the p-side of the VCSEL.

### B. FORMATION OF THE CURVED SURFACE

The curved mirror surface can be formed in multiple ways including, but not limited to, etching of a pre-patterned photoresist lens. The photoresist lens is often applied using local dispensing methods or using thermal reflow. Thermal reflow involves depositing photoresist (PR) on a surface, removing the PR from outside the area of interest, and melting the resulting cylinders/rectangular prisms to form lenses[7]. This shape can then be transferred into the surface through reactive ion etching.

### C. FIRST EXAMPLE

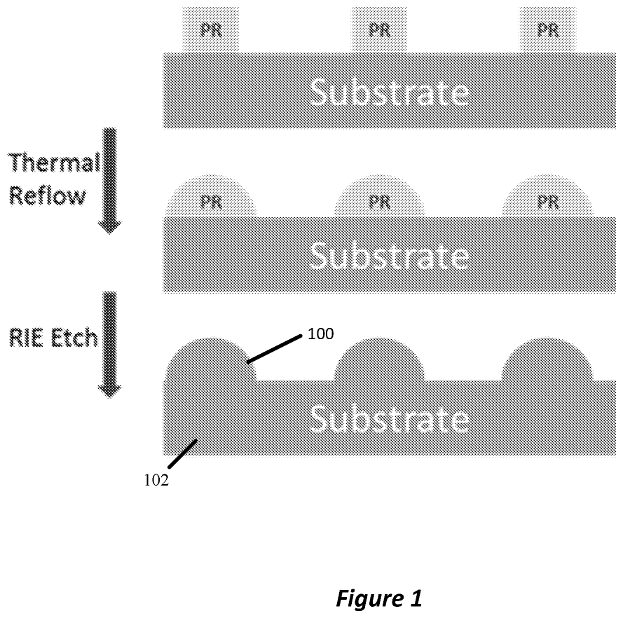

FIG. 1 illustrates an embodiment wherein the mirror 100 is formed on a surface of a substrate 102 comprising a VCSEL device structure, or on a surface of III-Nitride layers on the substrate. Specifically, the mirror 100 is grown on an n-GaN or un-intentionally doped (UID)-GaN surface grown above a tunnel junction contact to the p-GaN. A tunnel junction refers to a highly doped p⁺⁺n⁺⁺ junction. The III-N cavity may be grown by MOCVD to have a total thickness greater than 8 micrometers. A tunnel junction (TJ) is grown on the p-side of the device, followed by 1-2 micron n-GaN or UID-GaN. The top n-GaN or UID GaN is processed to have a curved surface above the aperture of the VCSEL. To etch the lens shape into the GaN, the layer that is being etched must be as thick as, or thicker than the thickness of the lens, often a few microns thick. The Ohmic contact should be on n-GaN or n⁺⁺GaN for the tunnel junction (TJ). Growing a tunnel junction contact allows that thick layer to be UID GaN, instead of the lossy n-GaN. In this way, more than 50% of the cavity can be composed of, or comprise, epitaxial UID GaN, minimizing the absorption loss in the cavity to increase device performance.

An example process includes the following steps.

1. Growing the following layers in order on a substrate: base epi layers of sacrificial InGaN etching layer, UID-GaN (7 μm thick), n-GaN (1000 nm thick) for cladding and n-contacting, InGaN multi quantum wells, AlGaN electron blocking layer (50 nm), p-GaN (300 nm thick), and p⁺⁺GaN (10 nm thick).

2. Then, conducting ion implantation to define the aperture.

3. After surface cleaning, regrowing n⁺⁺GaN (10 nm thick) to complete the tunnel junction.

4. Depositing n-GaN (1000 nm thick) for contacting and current spreading, and UID-GaN (3 μm) for forming the lens.

5. Dry etching mesas to define the devices.

6. Using thermal reflow of photoresist (PR in FIG. 1), etching a lens shape having curved surfaces in the UID-GaN down to the n-GaN with reactive ion etching (RIE).

7. Depositing dielectric distributed bragg reflector (DBR) mirrors over the curved surfaces.

8. Depositing contact metal, and flip chip bonding to a submount.

9. Removing the substrate through lateral photoelectrochemical etching of the sacrificial InGaN layer. Removing the substrate with this method allows for repeated reuse of the same substrate, thereby significantly reduces the cost of substrates. Another group has used a substrate to form a long cavity itself, in which case the substrate cannot be reused, leading to the cost of the substrate becoming very high [1].

10. Dry etching the thick UID-GaN to expose the n-GaN outside the aperture and deposit metal contacts.

11. Finally, depositing a planar dielectric DBR on the thick UID-GaN and the cavity is made significantly thicker.

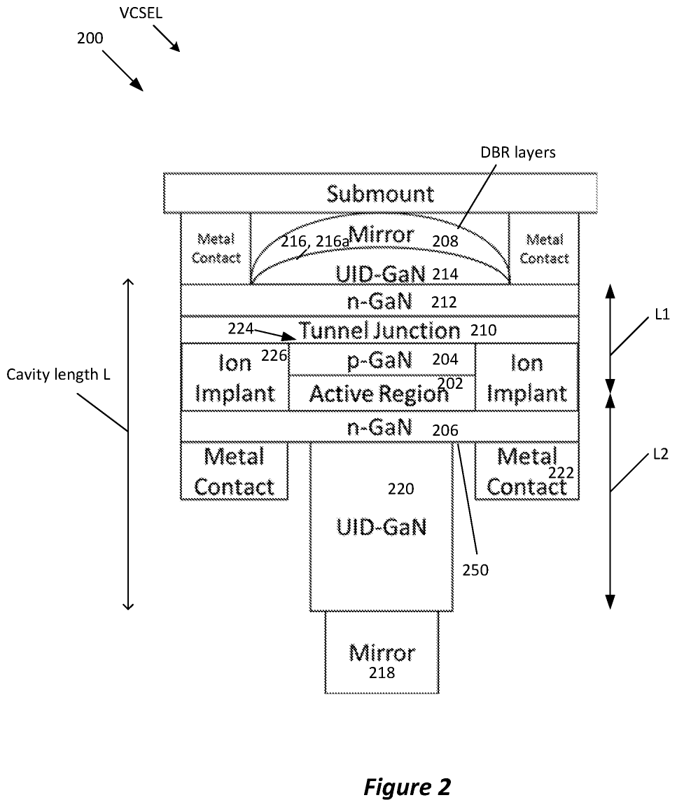

12. The resulting device structure is shown in FIG. 2. Alternatively, the flat mirror could be formed epitaxially between sacrificial InGaN layer and UID-GaN.

FIG. 2 illustrates a device 200 comprising a III-Nitride based VCSEL, the VCSEL comprising: a III-Nitride active region 202 between a p-type III-Nitride layer (or region 204 e.g., p-GaN) and an n-type III-Nitride layer (or region 206 e.g., n-GaN); and a curved mirror 208 on or above the p-type III-Nitride layer 204 such that the p-type III-Nitride layer or region 204 is between the III-Nitride active region 204 and the curved mirror 208.

FIG. 2 further illustrates the VCSEL further comprises one or more tunnel junction layers 210 on the p-type III-Nitride layer 204, wherein the curved mirror 208 is formed on or above the tunnel junction or tunnel-junction layers such that the tunnel junction is (or the tunnel junction layers are) between the curved mirror 208 and the p-type III-Nitride layer 204. The tunnel junction 210 may comprise a tunnel junction between the p-type III-Nitride layer and an n-type layer (e.g., second n-type III-Nitride layer 212).

FIG. 2 further illustrates the VCSEL comprises a III-nitride region 214 (e.g., second n-type region comprising n-GaN and/or UID GaN) on or above the tunnel-junction layer(s) or on or above the second n-type III-Nitride layer 212, wherein the curved mirror 208 includes the second n-type III-Nitride region 214 and the second the n-type III-Nitride region has a curvature forming the curved mirror. In one more examples, the second n-type III-Nitride region 214 has an etched surface 216 having the curvature.

FIG. 2 further illustrates the VCSEL further comprises a flat mirror 218 (e.g., flat distributed bragg reflector). In one or more examples, the curved mirror comprises a curved DBR mirror. The III-Nitride active region is between the flat DBR mirror and the curved DBR mirror, and the flat DBR mirror and the curved DBR mirror define a cavity of the VCSEL having a cavity length. In one or more examples, the cavity length L is defined as the distance between the interface of the curved mirror with the VCSEL structure and the interface of the flat mirror with the VCSEL structure. In one more examples, a distance L1 between the curved mirror (e.g., interface of the curved mirror and the VCSEL structure) and the active region (e.g., the center of the active region) is shorter than the distance L2 between flat mirror 218 (e.g., interface of the flat mirror and the VCSEL structure) and the active region (e.g., the center of the active region).

FIG. 2 further illustrates the VCSEL further comprises an unintentionally doped gallium nitride (UID GaN) layer 220 on the n-type III-Nitride layer 206, wherein the UID GaN is thick (thicker than the n-type III-Nitride layer) and a metal contact or Ohmic contact material 222 is deposited on the exposed surface of the n-GaN.

FIG. 2 further illustrates an aperture 224 in the cavity, wherein the curved mirror has a curvature focusing electromagnetic radiation within (or at least 90% within) the aperture. In the example of FIG. 2, the aperture is a current aperture in the p-type III-Nitride layer and the active region, the current aperture defined by a region 226 (e.g., implanted region or current barrier) around the current aperture preventing flow of the current in the implanted region or the barrier and diverting flow of the current to the current aperture.

### D. SECOND EXAMPLE

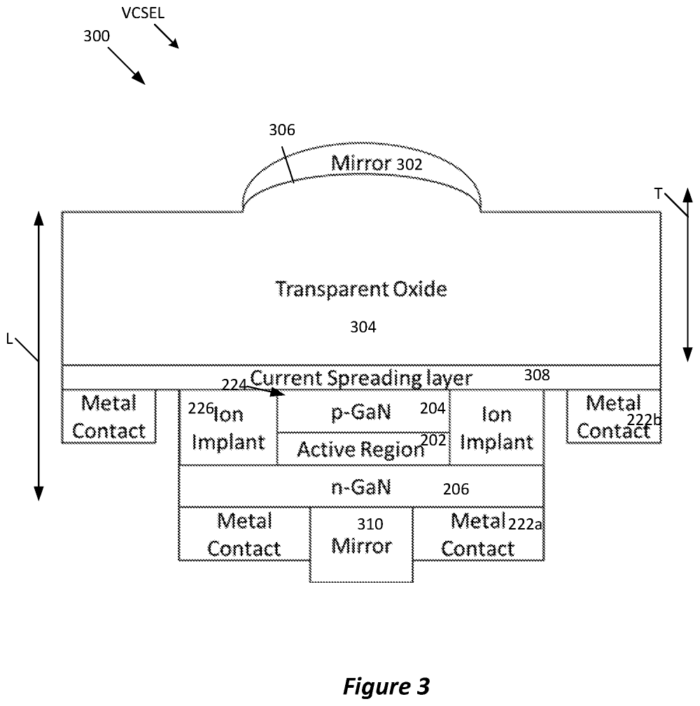

In a second embodiment, the lens shape is formed in a transparent oxide material, such as ZnO, Ga₂O₃; Al₂O₃, etc. This allows the cavity to be dominated by the nearly lossless oxide. The oxide material can either be grown on or above the III-N surface, or bonded to the surface through direct wafer bonding. Undoped or doped single crystal ZnO can be grown by MOCVD or through the hydrothermal method [8,9]. The III-nitride materials may also be grown by MOCVD. Using thermal reflow lens shapes can be etched in the ZnO, which is followed by deposition of the DBR mirror. An example process using direct wafer bonding is as follows. The epitaxial layers are grown via MOCVD. The aperture is then defined via ion implantation followed by deposition of a current spreading layer, either a tunnel junction or indium tin oxide (ITO). Concurrently, a double side polished sapphire wafer has had lens shapes etched into one side. The epi layers are then wafer bonded to the sapphire wafer with thin SiO₂ interlayers. The substrate is removed through photoelectrochemical etching of a sacrificial layer. Mesas are etched and metal contacts are deposited. SiO₂/Ta₂O₅ dielectric distributed Bragg Reflectors are then deposited on both sides of the cavity. The result is shown in FIG. 3.

FIG. 3 illustrates a device 300 comprising a III-Nitride based VCSEL comprising a curved mirror 302 formed on or in a Transparent Oxide (TO) material 304. The transparent Oxide (TO) material is on or above the p-type III-Nitride layer 204 such that the p-type III-Nitride layer is between a III-Nitride active region 202 and the Transparent Oxide (TO) material 304 having a curved surface 306 forming the curved mirror.

FIG. 3 further illustrates a layer 308 comprising or forming a III-Nitride tunnel junction and/or current spreading layer on the p-type III-Nitride layer 204, wherein the transparent Oxide (TO) material is grown on or above the layer 308 (III-Nitride tunnel junction and/or current spreading layer) such that the III-Nitride tunnel junction and/or current spreading layer is between the curved mirror 302 and the p-type III-Nitride layer 204.

FIG. 3 further illustrates the VCSEL further comprises a second mirror 310 (e.g., flat DBR mirror). The flat DBR mirror and the curved DBR mirror define a cavity of the VCSEL. In one or more examples, the cavity has a length L is defined as the distance between the interface of the curved mirror with the VCSEL structure and the interface of the flat mirror with the VCSEL structure. In one or more examples, a maximum thickness T of the transparent oxide material is more than 5 micrometers.

### E. EXAMPLE EMBODIMENTS

VCSELs according to embodiments described herein can be embodied in many ways including, but not limited to, the following (referring also to FIGS. 2-3).

1) One or more III-Nitride based VCSELs each comprising a curved mirror 208, 302 formed on or above p-type III-Nitride layers.

2) The VCSELs of clause 1, wherein the curved mirror is formed on or above the tunnel-junction layers 210 in the VCSELs.

3) The VCSELs of clause 1 or 2, wherein the total cavity length L of each of the VCSELs is more than 8 microns.

4) The VCSELs of any of the clauses 1-3, wherein more than 50% of the cavity in each VCSEL is composed of epitaxially grown GaN, UID-GaN or n-type GaN.

5) The VCSELs of any of the clauses 1-4, wherein all of the III-Nitride layers of VCSELs are grown epitaxially by Metal Organic Vapor Phase Deposition (MOCVD).

6) The VCSELs of any of the clauses 1-5, wherein, in each VCSEL, the distance between the DBR mirror on the curved mirror and the active layer is shorter than the distance between another DBR mirror on a flat III-Nitride layer and the active layer.

7) The VCSELs of any of the clauses 1-6, wherein fabrication of each of the VCSELs comprises depositing thick UID GaN on n-GaN, then etching UID GaN to n-GaN where the metal contact or Ohmic contact is deposited on the n-GaN.

8) The VCSELs of any of the clauses 1-7, wherein the VCSELs are grown on a GaN substrate and the GaN substrate is removed after fabrication of the VCSELs. After removing the GaN substrate, the GaN substrate is reused more than 3 times (e.g., for growth of more VCSEL(s), e.g., using the methods described herein).

9) A Long cavity VCSEL composed with III-Nitride layers, transparent Oxide (TO) materials, and a curved mirror

10) One or more VCSELs each comprising a curved mirror formed on transparent Oxide (TO) materials such as ZnO, Ga₂O₃, Al₂O₃, etc.

11) The VCSELs of clause 10, wherein the transparent Oxide (TO) materials, such as ZnO, Ga2O3, Al₂O₃ and etc., are grown or bonded on or above the current spreading layer such as IIII-Nitride tunnel junction, ITO, Ga-doped ZnO, and transparent conductive oxide (TCO) materials.

12) The VCSELs of clauses 10 or 11, wherein the total cavity length of each of the VCSELs is more than 8 microns.

13) The VCSELs of any of the clauses 10-13, wherein all of the III-Nitride layers of each of the VCSELs are grown epitaxially by MOCVD.

14) The VCSELs of any of the clauses 10-13, wherein the thickness of the transparent oxide is more than 5 μm

15) The VCSELs of any of the clause 10-14, wherein the VCSELs are grown on a GaN substrate and the GaN substrate is removed after formation of the VCSELs. After removing the GaN substrate, the GaN substrate is reused more than 3 times (e.g., for growth of more VCSEL(s), e.g., using the methods described herein).

### F. FURTHER EMBODIMENTS

VCSELs according to embodiments described and illustrated herein can be embodied in many ways including, but not limited to, the following (referring also to FIGS. 2-4).

1. A device, comprising:
a VCSEL, comprising:

a III-Nitride active region 202 between a p-type III-Nitride layer 204 and an n-type III-Nitride layer 206; and

a curved mirror 208 on or above the p-type III-Nitride layer such that the p-type III-Nitride layer is between the III-Nitride active region and the curved mirror.

2. The device of clause 1, wherein the VCSEL further comprises:

one or more tunnel junction layers 210 on the p-type III-Nitride layer, wherein the curved mirror is formed on or above the tunnel-junction layers such that the tunnel-junction layers are between the curved mirror and the p-type III-Nitride layer.

3. The device of clause 2, wherein the VCSEL further comprises:

a second n-type III-Nitride layer or region 214 on or above the tunnel-junction layers, wherein the curved mirror 208 includes the second n-type III-Nitride region 214 and the second the n-type III-Nitride region has a curvature 216a forming the curved mirror.

4. The device of clause 3, wherein the second n-type III-Nitride region 214 has an etched surface having the curvature 216a.

5. The device of clauses 3 or 4, wherein the second n-type III-Nitride region comprises n-type gallium nitride or unintentionally doped gallium nitride.

6. The device of any of the preceding clauses 1-5, wherein:

the VCSEL further comprises a flat DBR mirror 218,

the curved mirror comprises 208 a curved DBR mirror,

the III-Nitride active region is between the flat DBR mirror and the curved DBR mirror, and

the flat DBR mirror and the curved DBR mirror define a cavity of the VCSEL.

7. The device of any of the preceding clauses 1-6, wherein a total cavity length L of the VCSEL's cavity is more than 8 microns.

8. The device of any of the preceding clauses 1-7, wherein more than 50% of the VCSEL's cavity is composed of, comprises, or consists essentially of epitaxially grown GaN, UID GaN or n-type GaN.

9. The device of any of the preceding clauses 1-8, wherein all of the III-Nitride layers 202, 204, 206, 210, 212, 214, 220 of the VCSEL are grown epitaxially by metal organic chemical vapor deposition (MOCVD).

10. The device of any of the preceding clauses 1-9, wherein:

the VCSEL further comprises a flat III-nitride layer 220 and a first Distributed Bragg Reflector (DBR) 218 on the flat III-nitride layer,

the active region 202 is between the flat III-nitride layer and the curved mirror,

the curved mirror includes a second Distributed Bragg Reflector (DBR),

a distance L1 between the second DBR and the active region 202 is shorter than the distance L2 between first DBR and the active region.

11. The device of any of the preceding clauses 1-10, wherein the VCSEL further comprises an unintentionally doped gallium nitride (UID GaN) layer 220 on the n-type III-Nitride layer 206, wherein the UID GaN is thick (thicker than the n-type III-Nitride layer) and wherein:

the n-type III-Nitride layer 206 comprises n-type gallium nitride (n-GaN),

the UID GaN is etched to expose a surface 250 of the n-GaN, and

a metal contact 222 or Ohmic contact material is deposited on the exposed surface 250 of the n-GaN.

12. A method of fabricating the VCSEL of any of the preceding clauses 1-11, comprising:

growing the VCSEL structure on a gallium nitride (GaN) substrate; and

removing the GaN substrate so that the GaN substrate can be re-used more than 3 times.

13. A device, comprising:

a III-Nitride based Vertical Cavity Surface Emitting Laser (VCSEL), comprising a curved mirror 302 formed on or in a Transparent Oxide (TO) material 304.

14. The device of clause 13, wherein the transparent Oxide (TO) material comprises ZnO, Ga₂O₃, or Al₂O₃, etc.

15. The device of clauses 13 or 14, wherein the VCSEL further comprises:

a III-Nitride active region 202 between a p-type III-Nitride layer 204 and an n-type III-Nitride layer 206; and

the transparent Oxide (TO) material 304 on or above the p-type III-Nitride layer such that the p-type III-Nitride layer is between the III-Nitride active region and the Transparent Oxide (TO) material having a curved surface forming the curved mirror.

16. The device of clauses 13, 14, or 15, further comprising:

a III-Nitride tunnel junction 210, 308 on the p-type III-Nitride layer 204, wherein the transparent Oxide (TO) material 304 is grown on or above the IIII-Nitride tunnel junction such that the III-Nitride tunnel junction is between the curved mirror 302 and the p-type III-Nitride layer 204.

17. The device of any of the clauses 13-16, wherein:

the VCSEL further comprises a flat DBR mirror 310,

the curved mirror 302 comprises a curved DBR mirror,

the flat DBR mirror and the curved DBR mirror define a cavity of the VCSEL.

18. The device of any of the preceding clauses 13-17, wherein a total cavity length L of the VCSEL's cavity is more than 8 micrometers.

19. The device of any of the preceding clauses 13-18, wherein all of the III-Nitride layers 204, 202, 206, 308 of the VCSEL are grown epitaxially by metal organic chemical vapor deposition (MOCVD).

20. The device of any of the preceding clauses 13-19, wherein a thickness T of the transparent oxide material is more than 5 micrometers.

21. A method of fabricating the VCSEL of any of the preceding clauses, comprising:

growing the VCSEL structure on a gallium nitride substrate; and

removing the GaN substrate so that the GaN substrate can be re-used as a growth substrate more than 3 times.

22. The VCSEL of any of the preceding clauses 1-22, further comprising a flat mirror 310, wherein the active region 202 is in a cavity between a flat DBR mirror 310 and the curved mirror 302 comprising a curved DBR mirror, and:

the active region emits electromagnetic radiation in response to:
a voltage applied between the p-type III-Nitride layer 204 and the n-type III-Nitride region 206 (e.g., voltage applied across or between contacts 222a and 222b), and/or
one or more recombinations (in the active region 202) each comprising recombination of a hole (from the p-type III-Nitride layer) with an electron (from the n-type III-Nitride layer), and

the electromagnetic radiation is reflected between the curved DBR mirror 208, 302 and the flat DBR mirror 218, 310 so as to optically pump the III-Nitride active region 202 and generate stimulated emission of the electromagnetic radiation having an intensity such that gain of the electromagnetic radiation occurs and the VCSEL lases and emits the electromagnetic radiation comprising coherent electromagnetic radiation through the flat mirror 218, 310 and/or the curved mirror 208, 302.

23. The VCSEL of clause 22, further comprising an aperture 224 in the cavity, wherein the curved mirror has a curvature focusing the electromagnetic radiation within (or at least 90% within, or such that at least 90% of the intensity of the electromagnetic radiation is within) the aperture.

24. The VCSEL of clause 23, wherein:

current flows in response to the voltage, and

the aperture 224 is a current aperture in the p-type III-Nitride layer and the active region, the VCSEL further comprising an implanted region 226 or current barrier around the current aperture preventing flow of the current in the implanted region or the barrier and diverting flow of the current to the current aperture.

25. The VCSEL of clauses 22, 23 or 24, wherein the curved mirror has a curvature focusing the electromagnetic radiation so that, when a length of the cavity varies from its designed length due to thermal effects, the VCSEL continues to lase when an otherwise similar VCSEL having a flat mirror instead of the curved mirror would cease lasing under the same conditions.

### G. EXAMPLE PROCESS STEPS

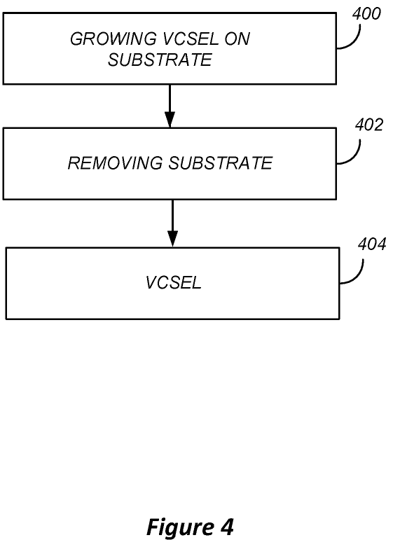

FIG. 4 is flowchart illustrating a method of fabricating the VCSEL.

Block 400 represents growing the VCSEL structure on a III-Nitride (e.g., gallium nitride) substrate. The VCSEL structure can be as described in any of the examples in sections E and F above.

Block 402 removing the GaN substrate so that the GaN substrate can be re-used as a growth substrate more than 3 times. The step can comprise mounting the VCSEL on a submount.

Block 404 represents the end result, a VCSEL. Example VCSELs include any of the VCSELs described in sections E and F or illustrated in FIG. 2 or FIG. 3. In one or more examples, blocks 400-402 are repeated at least 3 times with the substrate from a previous growth of the VCSEL re-used for the growth of the VCSEL in the next iteration of Blocks 400.

### H. NOMENCLATURE

The terms “III-Nitride”, “III-N”, and “GaN” refer to any alloy of group III (B,Al,Ga,In) nitride semiconductors that are described by B_{w}AlₓGa_{y}In_{z}N, where 0≤w≤1, 0≤x≤1, 0≤y≤1, 0≤z≤1, and w+x+y+z=1. Compositions can range from containing a single group III element to all four group III elements. These materials can, and often, include dopants and impurities.

As used herein, n-GaN/UID-GaN refers to low doped GaN that is n-type. UID GaN comprises unintentional doping which is generally n-type or semi-insulating. The optimum doping level to balance electrical conductivity and absorption will depend on the final device design used.

### I. ADVANTANES AND IMPROVEMENTS

Embodiments of the present invention provide the following advantages, for example.

1. High yield: increase the tolerance for cavity length variability and design of the VCSEL structure.

2. Reduced cost: there is no substrate thinning. Just epitaxial growth or TO bonding means very good uniformity.

### H. REFERENCES FOR SECTION I

The following references are incorporated by reference herein.

1. T. Hamaguchi, H. Nakajima, M. Tanaka, M. Ito, M. Ohara, T. Jyoukawa, N. Kobayashi, T. Matou, K. Hayashi, H. Watanabe, R. Koda, and K. Yanashima, “Sub-milliampere-threshold continuous wave operation of GaN-based vertical-cavity surface-emitting laser with lateral optical confinement by curved mirror,” Appl. Phys. Express 12, 044004 (2019).

2. T. Hamaguchi, M. Tanaka, J. Mitomo, H. Nakajima, M. Ito, M. Ohara, N. Kobayashi, K. Fujii, H. Watanabe, S. Satou, R. Koda, and H. Narui, “Lateral optical confinement of GaN-based VCSEL using an atomically smooth monolithic curved mirror,” Sci. Rep. 8, 10350 (2018).

3. B. Guan, P. Li, S. Arafin, Y. Alaskar, and K. L. Wang, “Investigation of single-mode vertical-cavity surface-emitting lasers with graphene-bubble dielectric DBR,” Photonics Nanostructures—Fundam. Appl. 28, 56-60 (2018).

4. A. Tarraf, F. Riemenschneider, M. Strassner, J. Daleiden, S. Irmer, H. Halbritter, H. Hillmer, and P. Meissner, “Continuously Tunable 1.55-&amp;lt;tex&amp;gt;$mu$&amp;lt;/tex&amp;gt;m VCSEL Implemented by Precisely Curved Dielectric Top DBR Involving Tailored Stress,” IEEE Photonics Technol. Lett. 16, 720-722 (2004).

5. T. Hamaguchi, N. Fuutagawa, S. Izumi, M. Murayama, and H. Narui, “Milliwatt-class GaN-based blue vertical-cavity surface-emitting lasers fabricated by epitaxial lateral overgrowth,” Phys. status solidi 213, 1170-1176 (2016).

6. C. A. Forman, S. Lee, E. C. Young, J. A. Kearns, D. A. Cohen, J. T. Leonard, T. Margalith, S. P. DenBaars, and S. Nakamura, “Continuous-wave operation of m-plane GaN-based vertical-cavity surface-emitting lasers with a tunnel junction intracavity contact,” Appl. Phys. Lett. 112, 111106 (2018).

7. H. W. Choi, C. Liu, E. Gu, G. McConnell, J. M. Girkin, I. M. Watson, and M. D. Dawson, “GaN micro-light-emitting diode arrays with monolithically integrated sapphire microlenses,” Appl. Phys. Lett. 84, 2253-2255 (2004).

8. W. Lin, D. Chen, J. Zhang, Z. Lin, J. Huang, W. Li, Y. Wang, and F. Huang, “Hydrothermal Growth of ZnO Single Crystals with High Carrier Mobility,” 9, 4378-4383 (2009).

9. Y. Ma, G. Du, J. Yin, al-, B. Hahn, G. Heindel, E. Pschorr-Schoberer, and W. Gebhardt, MOCVD Layer Growth of ZnO Using DMZn and Tertiary Butanol (1998), Vol. 13.

10. “Vertical cavity lasers with monolithically integrated refractive microlenses,” (1997).

11. “Optical device and method of manufacturing the same,” (1997).

12. “Curved mirror resonator,” (1997).

13. “Vertical cavity surface emitting laser,” (2002).

14. U.S. Pat. No. 6,661,829 B2,

15. French patent No. FR2768566A1,

16. U.S. Pat. No. 6,178,035B1,

17. PCT International Patent Application No. WO1997040558A1.

II. III-Nitride Vertical-Cavity Surface Emitting Lasers with a High Indium Content Active Region

### A. INTRODUCTION

Vertical-cavity surface-emitting lasers (VCSELs) are used extensively in data communications and various sensing applications, including vehicle LiDAR, 3D imaging, and gas detection. The majority of these VCSELs utilize a GaAs cavity and active region, or InGaAsP, or monolithic InP. The InP/GaAs material system is the dominant system used for long-wavelength VCSELs. While InP/GaAs-based VCSELs benefit from relatively simple manufacturing processes due to lattice matching between the active region and substrate, they suffer from low thermal stability. This requires significant investments of money and space for cooling systems when using these devices, and limits the ability to utilize one of VCSEL's main features, high-powered 2-dimensional arrays. Alternatively, the wide bandgap III-Nitride system has far superior thermal stability. However, the large lattice mismatch and disparate growth conditions between GaN and InN have made it difficult to manufacture functioning devices at long wavelengths.

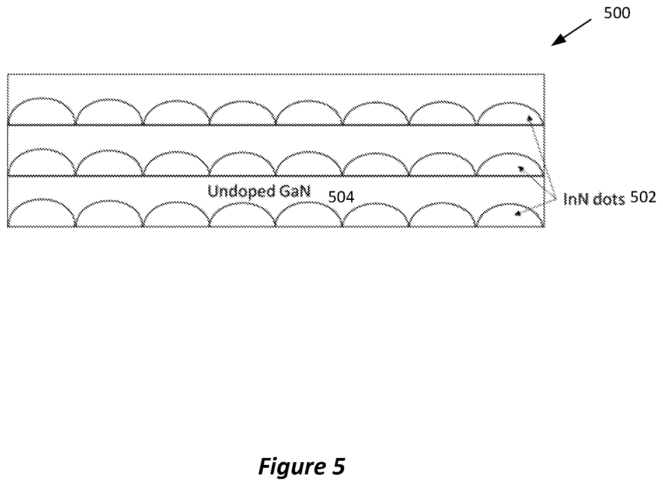

This section describes a III-N VCSEL comprising an epitaxially grown active region of high In content dots or dashes originating from coalesced dots. A drawing of the dots active region is shown in FIG. 5. FIG. 5 shows an example where the active region 500 comprises indium nitride (InN) dots 502 in undoped gallium nitride layers 504. The predominate issue with using high In-content quantum dots as an active region is in the difficulty of growing GaN layers above it. If the growth above the active region is done at standard GaN growth conditions (usually around 1000 degrees Celsius), the high indium content dots (growth temperature around 600-650 degrees Celsius) will be destroyed. Low temperature growth of the GaN close to the dot growth temperature is needed for retaining the quality of the active region, but low temperature growth leads to low hole concentrations in p-GaN. The lower growth temperatures are more acceptable for growing n-type III-Nitrides than p-type.

Therefore, in one embodiment, the p-GaN is grown at standard GaN growth conditions of 1000 degrees before the active region. This is followed by growth of n-GaN at a temperature where the active region is not damaged. The p-GaN can then be activated through sidewall activation after mesas are defined, or through the p-GaN surface activation after substrate removal. Low growth temperature refers to growth where the wafer is at less than 800° C.

### B. FIRST EXAMPLE DESIGN

An example embodiment of the present invention incorporates two dielectric Distributed Bragg Reflectors (DBR), an ion implantation defined aperture, and a long, primarily oxide cavity. In one or more examples, a long cavity may be advantageous over a shorter cavity due to superior thermal management, further supporting high thermal stability operation because the gain spectrum always overlaps with a cavity mode due to small mode spacing of a long cavity. For the same reason, the tolerance to wafer and processing variability is much higher for long cavity VCSELs relative to short cavity VCSELs, which can lead to higher production yields.

The III-N epitaxial layers are grown by MOCVD on a semipolar or nonpolar GaN substrate; semipolar and nonpolar III-Nitride offer higher material gain (up to 3 times higher) compared to c-plane GaN substrates due to uni-axial strain vs. biaxial strain. The layers comprise: a sacrificial InGaN etching layer (grown at 875° C.), a current spreading layer composed of n-GaN (100-1000 nm thick), n⁺⁺/p⁺⁺ tunnel junction (grown at 900-1000° C.) or other current spreading layers, p-GaN (50-200 nm thick) (grown at 900-1000° C.), high In content dots (grown at 600-650° C.), and low doped n-GaN (10-200 nm thick and grown at 600-650° C.).

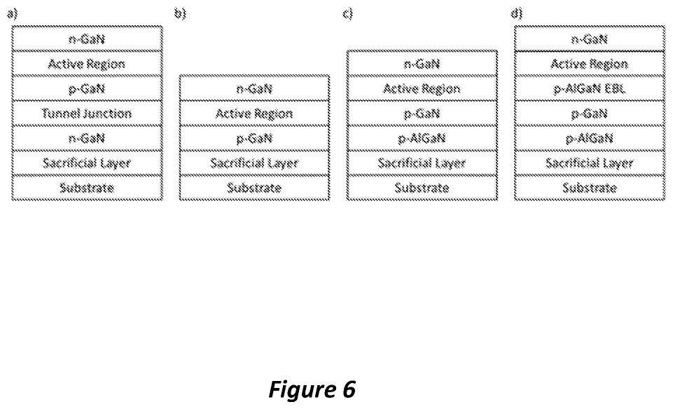

FIG. 6(a) illustrates an embodiment with a tunnel junction (TJ). FIG. 6(b) illustrates an alternative epitaxial structure embodiment including a transparent conductive oxide (TCO), such as doped ZnO or ITO, used for current spreading, and which can be deposited later on p-GaN during processing. FIG. 6(c) illustrates yet another embodiment, wherein the current spreading layer can be formed from growing a thin (2 nm) p⁺⁺-AlGaN layer before the p-GaN (instead of the n-GaN and n⁺⁺ GaN)—i.e., using a two dimensional hole gas at the p⁺⁺ AlGaN/p-GaN interface as the current spreading layer [10]. If the carrier overflow becomes a big issue, an AlGaN electron blocking layer (EBL) can be inserted before the active layer, as shown in FIG. 6(d).

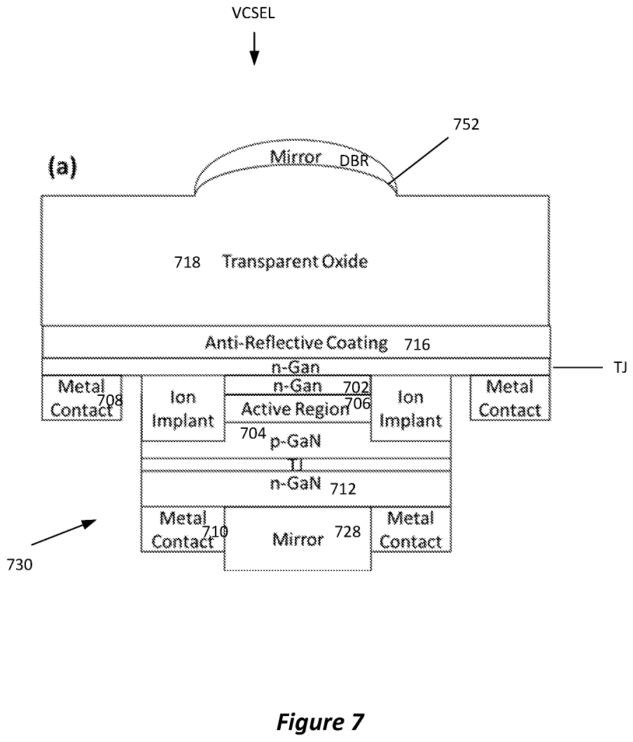

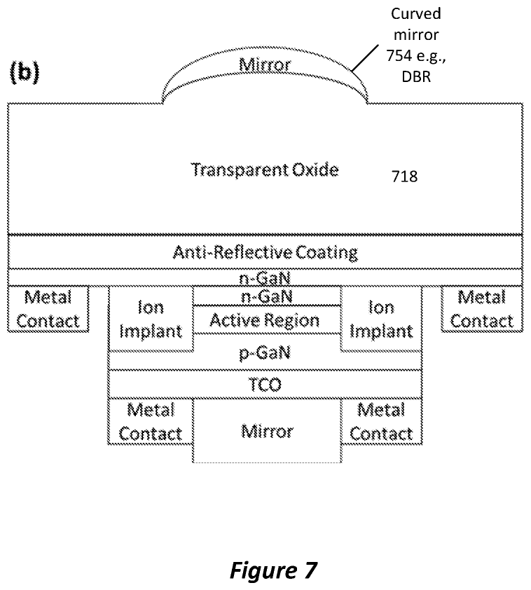

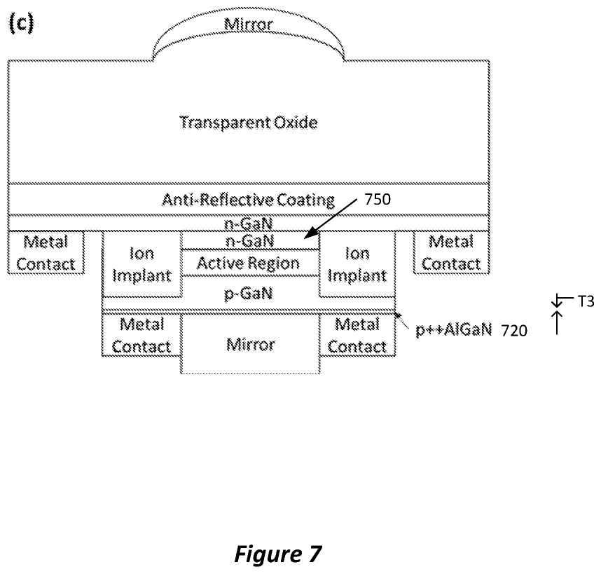

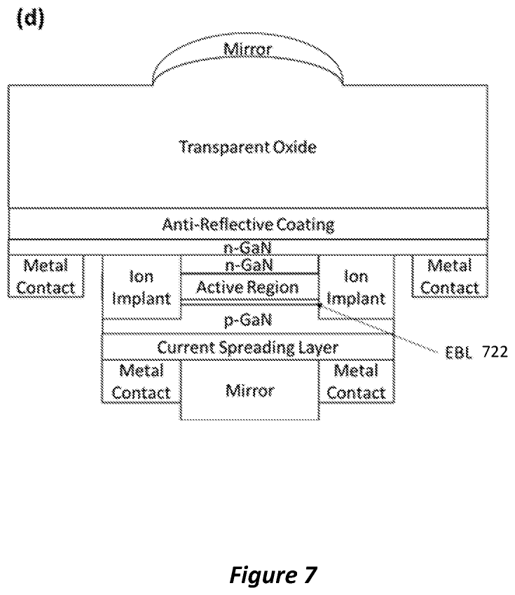

FIGS. 7(a)-(d) illustrate device structures that may include the epitaxial structures illustrated in FIGS. 6(a)-(d), for example. After growth, ion implantation into the active layer is performed to define the aperture in the device structures. Then, a regrowth of n-GaN is performed to form a contacting layer. At the GaN/Oxide interface, the refractive index difference leads to potentially unwanted reflections. In the case that these reflections lead to detrimental device performance, an antireflection coating can be deposited on the surface. Example antireflection coatings may consist of or comprise HfO₂, or Ta₂O₅, or another transparent material with a refractive index between that of GaN and that of the cavity oxide. Mesas are then etched to expose the sacrificial layer. This is followed by the addition of a thick un-doped oxide layer to form the cavity, which allows the cavity to be dominated by a low loss material. An example undoped thick transparent oxide layer includes, but is not limited to, ZnO grown via the hydrothermal method or MOCVD. Alternatively, the III-Nitride devices can be wafer bonded to an oxide wafer, such as Al₂O₃ to form the cavity. A curved lens shape is formed in the transparent oxide material through thermal reflow, and is followed by Distributed Bragg Reflector (DBR) deposition as shown in FIG. 7(a). The GaN substrate is then removed with photoelectrochemical etching, and the p-GaN is activated through the surface or sidewalls by using thermal annealing at 600 degrees Celsius.

When the current spreading is provided by the transparent conductive oxide (TCO) 718, as shown in FIG. 7(b), the p-GaN can be activated by thermal annealing through the TCO or before the TCO deposition. Surface activation generally leads to more complete activation and lower operating voltages compared to sidewall activation. The TCO can be made of indium tin oxide (ITO), cadmium oxide (CdO), doped zinc oxide (ZnO-Ga), or any other convenient TCO (for example). In one embodiment when the current spreading 720 is composed of a thin p⁺⁺AlGaN layer, as shown in FIG. 7(c), the p⁺⁺-AlGaN and p-GaN are activated at the same time from the surface.

A second mesa etch is performed to expose the n-GaN for contacting. Metal contacts of Ti/Au and Pd/Au are deposited on the n-GaN and the p⁺⁺-AlGaN, respectively, for the p⁺⁺-AlGaN current spreading design. For the designs with the tunnel junction or the TCO, a common contacting metal of Ti/Au can be used and deposited in one step, which reduces the fabrication steps, and therefore the time and money for production. Finally, a SiO₂/Ta₂O₅ DBR is deposited above the aperture on the p-side.

The device structure and some possible variants described above are shown in FIGS. 7(a)-7(d).

FIGS. 7(a)-(d) illustrate a III-Nitride Vertical Cavity Surface Emitting Laser VCSEL comprising an n-type III-Nitride region 702; a p-type III-Nitride region 704; and a III-nitride active region 706 between the n-type III-Nitride region and the p-type III-Nitride region, wherein the III-Nitride active region comprises partially or fully relaxed high indium content III-Nitride quantum dots 502 having an indium content of more than 30%.

In various examples, the VCSEL further includes a first metal contact 708 to the n-type III-Nitride region 702; and a second metal contact 710 to the p-type III-Nitride region 704 or to a second n-type III-Nitride region 712 on the p-type III-Nitride region. In various examples, the first metal contact and the second metal contact are on the same side of the III-Nitride VCSEL. The second n-type III-Nitride region 712 forms a tunnel junction (TJ) with the p-type III-Nitride region 704.

FIG. 7(a) further illustrates an example wherein the III-Nitride VCSEL further includes an antireflection coating 716 between a transparent oxide material 718 and the GaN 702 so as to suppress unwanted reflections at an interface between the GaN and the transparent oxide material.

FIGS. 7(a)-(d) illustrates the VCSEL includes a p-n junction 724 comprising the p-type III-Nitride region, the n-type III-nitride region, and the III-Nitride active region between the p-type III-Nitride region and the n-type III-nitride region; a transparent oxide 718 including a curved mirror 726 located on the n-type GaN side of the p-n junction, and wherein no curved mirror is located on the p-type GaN side of the p-n junction.

FIGS. 7(a)-7(d) further illustrate the VCSEL further includes a flat mirror 728, wherein the active region is in a cavity between a flat DBR mirror and a curved mirror comprising a curved DBR mirror on an n-type side of the VCSEL.

FIGS. 7(a)-(d) further illustrate the VCSEL structure includes a mesa 730.

### C. SECOND EXAMPLE DESIGN

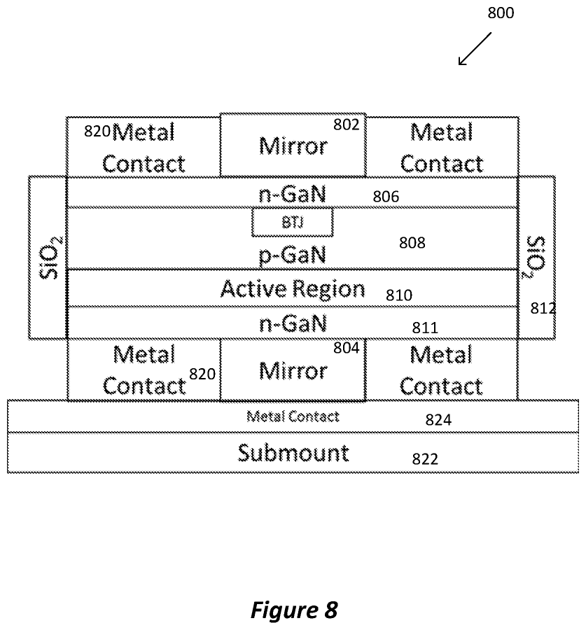

FIG. 8 illustrates a second example embodiment of the present invention comprising a device 800 incorporating two dielectric distributed Bragg Reflectors 802, 804, a buried tunnel junction defined aperture (BTJ), and a shorter cavity. The first III-N epitaxial layers may be grown by MOCVD on a semipolar or nonpolar GaN substrate and consist of or comprise: a sacrificial InGaN etching layer, a current spreading layer composed of n-GaN 806, and a n⁺⁺GaN tunnel junction layer. P⁺⁺GaN (10 nm thick) is then grown and etched down to the n-GaN 806 outside the aperture. The final epitaxial growth consists of or comprises a p-type III-Nitride layer 808 (e.g., P-GaN, 100 nm thick), an active region 810 (e.g., comprising high In-content dots), an n-type layer 811 (e.g., low doped n-GaN 90 nm thick), and highly doped n-GaN (10 nm) for contacting, as shown in FIG. 8. Then, mesas are etched and sidewall activation is done at 625° C. for 30 minutes. A SiO₂ layer 812 is deposited on the sidewalk to protect the active region during photoelectrochemical etching. A second etch is done to expose the sacrificial layers, a mirror 802 (e.g., DBR) is deposited over the aperture, and metal Ti/Au contacts 820 are deposited. The sample is then bonded to a submount 822 coated in Ti/In/Au 824 through eutectic thermo-compression bonding. The substrate is removed with Photoelectrochemical etching, metal contacts are deposited, and the mirror 804) (p-side DBR) is deposited. The result is shown in FIG. 8.

### D. DEVICE EMBODIMENTS FOR SECTION II

Examples include, but are not limited to, the following (referring also to FIGS. 5-8)

1. A III-Nitride VCSEL wherein both metal contacts 710, 708 for n-type and p-type are on the same side.

2. The VCSEL of embodiment 1), wherein the active region 706 is composed of partially or fully relaxed high indium content III-Nitride dots with the Indium content of more than 30%.

3. The VCSEL, of embodiments 1) or 2), wherein the growth of III-Nitride layers are grown on a semipolar or nonpolar orientation GaN substrate.

4. The VCSEL of embodiments 1), 2), or 3), wherein more than 50% of cavity is composed of transparent oxide (TO) material such as ZnO, Ga₂O₃ and others.

5. The VCSEL of embodiment 4), wherein an antireflection coating 716 is used to suppress unwanted reflections at the GaN/TO interface.

6. The VCSEL of embodiments 1)-5), wherein the current spreading layer is transparent conductive Oxide (TCO) or n-GaN and n⁺⁺-GaN which forms the tunnel junction with p⁺⁺-GaN.

7. The VCSEL of any of the previous embodiments, wherein the current spreading layer is composed of or incorporates a p⁺⁺AlGaN layer with a thickness of 1-5 nm.

8. The VCSEL of any of the previous embodiments, further including a transparent oxide with a curved mirror located n-GaN side of the junction, not p-GaN side.

9. The VCSEL of any of the previous embodiments, wherein the p-GaN is grown below the active region.

10. The VCSEL of any of the previous embodiments, wherein the p-GaN is activated after the removal of the substrate.

11. The VCSEL of any of the previous embodiments, wherein the growth temperature of n-GaN is lower than 800 degrees Celsius.

12. A device, comprising:

a III-Nitride VCSEL including:

an n-type III-Nitride region 702 (e.g., layer(s));

a p-type III-Nitride region 704 (e.g., layer(s));

a III-nitride active region 706 (e.g., layer(s)) between the n-type III-Nitride region and the p-type III-Nitride region, wherein the III-Nitride active region comprises partially or fully relaxed high indium content III-Nitride quantum dots having an indium content of more than 30%.

13. The device of embodiment 12, further comprising

a first metal contact 708 (e.g., comprising metal) on or to the n-type III-Nitride region; and

a second metal contact 710 (e.g. comprising metal) on or forming an electrical contact to, the p-type III-Nitride region 704 or to a second n-type III-Nitride region 712 on the p-type III-Nitride region, wherein the first metal contact 708 and the second metal contact 710 are on the same side of the III-Nitride VCSEL.

14. The device of any of the preceding embodiments 12-13, wherein the III-Nitride active region 706, the n-type III-Nitride region 702, and the p-type III-Nitride region 704 are grown on a semipolar or nonpolar orientation GaN substrate.

15. The device of any of the preceding embodiments, wherein the III-Nitride VCSEL comprises a cavity and more than 50% of the cavity comprises a transparent oxide (TO) material 718 such as, but not limited to zinc oxide (ZnO), gallium oxide, Ga₂O₃, aluminum oxide, Al₂O₃, sapphire, etc.

16. The device of embodiment 15, wherein:

the transparent oxide material is on or above the n-type III-Nitride region comprising gallium nitride (GaN),

the III-Nitride VCSEL further includes an antireflection coating 716 between the transparent oxide material 718 and the III-Nitride material (e.g., GaN 702) so as to suppress unwanted reflections at an interface between the III-Nitride material (e.g., GaN 702) and the transparent oxide material 718.

17. The device of any of the preceding embodiments, further comprising a current spreading layer including:

a transparent conductive oxide (TCO) 718 on or above the n-type III-nitride region 702, and/or

a second n-type III-Nitride region 712 including n-GaN and n⁺⁺-GaN which form a tunnel junction (TJ) with the p-type III-Nitride region 704 comprising p⁺⁺-GaN.

18. The device of any of the preceding embodiments 12-17, further comprising a current spreading layer including a p⁺⁺-AlGaN layer 720 having a thickness T3 of 1-5 nanometers (nm) (e.g., 1≤T3≤5 nm) wherein the p⁺⁺-AlGaN layer is on the p-type III-Nitride region 704.

19. The device of any of the preceding embodiments 12-18, wherein the VCSEL includes:

a p-n junction 750 comprising the p-type III-Nitride region 704, the n-type III-nitride region 702, and the III-Nitride active region 706 between the p-type III-Nitride region 704 and the n-type III-nitride region 702;

the p-type III-Nitride layer 704 comprising p-type GaN;

the n-type III-Nitride layer 702 comprising n-type GaN; and

a transparent oxide including 718 a curved mirror 752 located on or above the n-type GaN/III-Nitride 702 side of the p-n junction 750, and wherein no curved mirror is located on the p-type GaN/III-Nitride 704 side of the p-n junction.

20. The device of any of the preceding embodiments 12-19, wherein the p-type III-Nitride region 704 including p-GaN is grown below the III-Nitride active region 706.

21. The device of any of the preceding embodiments 12-20, wherein the p-type III-Nitride region 704 including p-GaN is activated after the removal of a substrate upon which the III-Nitride VCSEL is grown.

22. The device of any of the preceding embodiments 12-21, wherein a growth temperature of the n-type III-Nitride region 702 including n-type GaN is lower than 800 degrees Celsius.

23. The device of any of the preceding embodiments 12-22, wherein the III-Nitride VCSEL further includes:

a second n-type III-nitride region 712 on the p-type III-Nitride region 704, the second n-type III-Nitride region forming a tunnel junction TJ with the p-type III-Nitride region 704.

24. A method of making a device, comprising:

growing an epitaxial structure for a III-Nitride VCSEL including:

growing an n-type III-Nitride layer 702 at a growth temperature lower than 800 degrees Celsius;

growing a p-type III-Nitride layer 704; and

growing a III-nitride active region 706; and wherein:

the III-Nitride active region is between the n-type III-Nitride layer and the p-type III-Nitride layer.

25. The method of embodiment 24, wherein:

The epitaxial structure is grown on a substrate, and

the p-type III-Nitride layer 704 is grown prior to (or below) the III-Nitride active region 706 so that the p-type III-Nitride layer is between the substrate and the III-Nitride active region.

26. The method of embodiment 24, wherein the p-type III-Nitride layer 704 including p-GaN is activated after the removal of the substrate upon which the epitaxial structure is grown.

27. The method of any of the embodiments 24-26, further comprising:

forming a first metal contact 708 on or to the n-type III-Nitride layer 702; and

forming a second metal contact 710 to the p-type III-Nitride layer 704 or to a second n-type III-Nitride layer on the p-type III-Nitride layer, wherein the first metal contact and the second metal contact are on a same side of the III-Nitride VCSEL.

28. A VCSEL (e.g., of embodiments 1-23) fabricated using the method of any of the embodiments 24-27.

29. The method of any of the embodiments 24-28 wherein the III-Nitride active region 706 comprises partially or fully relaxed high indium content III-Nitride quantum dots having an indium content of more than 30%.

30. The method of embodiment 29, wherein the III-Nitride VCSEL further comprises

a current spreading layer including:
a transparent conductive oxide (TCO) 718 on or above the n-type III-nitride layer, and/or
the second n-type III-Nitride region 712 including a tunnel junction (TJ) with the p-type III-Nitride region 704, and/or
a p-type AlGaN layer 720 on the p-type III-Nitride layer and confining a two dimensional hole gas.

31. The device or method of any of the preceding embodiments 12-30, wherein the VCSEL further comprises:

a flat mirror 728, wherein the active region 706 is in a cavity between a flat mirror comprising a DBR and a curved mirror comprising a curved mirror 754 comprising a DBR on an n-type side of the VCSEL, and:

the active region 706 emitting electromagnetic radiation in response to:
a voltage applied between the p-type III-Nitride layer 704 and the n-type III-Nitride region 702 (e.g., voltage applied across or between the first metal contact 708 and the second metal contact 710), and/or
one or more recombinations (in the active region 706) each comprising recombination of a hole (from the p-type III-Nitride layer 704) with an electron (from the n-type III-Nitride layer 702); and

a transparent oxide 718 (e.g., ZnO) on or above the n-type III-Nitride layer 702.

Embodiments illustrated herein can achieve greater thermal stability and/or higher processing yield.

32. The device of any of the preceding embodiments 12-31, wherein the active region 706 comprises a quasi zero-dimensional structure (e.g., quantum dot, quantum dash, or quantum rod) characterized by quantum confinement in 3 dimensions.

### E. EXAMPLE PROCESS STEPS

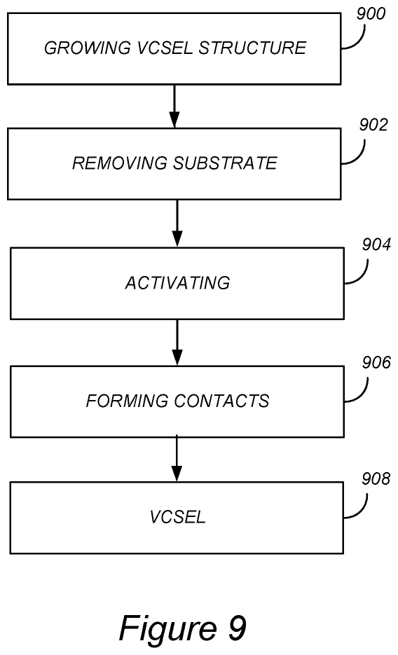

FIG. 9 is a flowchart illustrating a method of making a device.

Block 900 represents growing/depositing or forming an epitaxial structure for a III-Nitride VCSEL, e.g. on a substrate. The VCSEL can have the epitaxial structure of any of the examples in section D, for example. In one or more examples, the step comprises growing an n-type III-Nitride layer at a growth temperature lower than 800 degrees Celsius; growing a p-type III-Nitride layer; and growing a III-nitride active region; and wherein the III-Nitride active region is between the n-type III-Nitride layer and the p-type III-Nitride layer.

In one or more examples, the p-type III-Nitride layer is grown prior to (or below) the III-Nitride active region so that the p-type III-Nitride layer is between the substrate and the III-Nitride active region.

In one or more examples, the III-Nitride active region comprises partially or fully relaxed high indium content III-Nitride (e.g., quantum dots) having an indium content of more than 30% (e.g., in a range of 30%-100%).

In one or more examples, step comprising forming a current spreading layer includes forming a transparent conductive oxide (TCO) on or above the n-type III-nitride layer, or forming the second n-type III-Nitride region including a tunnel junction with the p-type III-Nitride region, or forming a p-type AlGaN layer on the p-type III-Nitride layer and confining a two dimensional hole gas.

Block 902 represents removing the substrate.

Block 904 represents activating the p-type III-Nitride layer. In one or more examples, the step comprises activating the p-type III-Nitride layer including p-GaN after the removal of the substrate upon which the epitaxial structure is grown.

Block 906 represents forming contacts to the VCSEL structure. In one or more examples, the step comprises forming a first metal contact to the n-type III-Nitride layer; and
forming a second metal contact to the p-type III-Nitride layer or to a second n-type III-Nitride layer on the p-type III-Nitride layer, wherein the first metal contact and the second metal contact are on a same side of the III-Nitride VCSEL.

Block 908 represents the end result, a VCSEL (e.g., as illustrated in FIG. 7, FIG. 8, fabricated using the method of any of the examples in section II part D.

### F. NOMENCLATURE

The terms “III-Nitride”, “III-N”, and “GaN” refer to any alloy of group III (B,Al,Ga,In) nitride semiconductors that are described by B_{w}AlₓGa_{y}In_{z}N, where 0≤w≤1, 0≤x≤1, 0≤y≤1, 0≤z≤1, and w+x+y+z=1. Compositions can range from containing a single group III element to all four group III elements. These materials can, and often, include dopants and impurities. High In content refers to alloys where z≥0.3.

As used herein, n-GaN/UID-GaN refers to low doped GaN that is n-type. UID GaN comprises unintentional doping which is generally n-type or semi-insulating. The optimum doping level to balance electrical conductivity and absorption will depend on the final device design used.

### G. ADVANTAGES AND IMPROVEMENTS FOR SECTION II

Vertical-cavity surface-emitting lasers (VCSELs) are used extensively in data communications, mainly due to their low-divergence, circular output beams, and single-mode operation [1]. The majority of these VCSELs utilize a GaAs cavity and active region that emits at a wavelength of 850 nm. There has been a strong push to move towards 1300 nm and 1550 nm emission as silica fibers have low attenuation at these wavelengths, opening up new opportunities for longer transmission distances, free-space transmission, and wavelength-division multiplexing. Additionally, these longer wavelengths are of interest in various sensing applications, including vehicle LiDAR, 3D imaging, and gas detection². These longer wavelength VCSELs have a variety of different active regions and cavities, including InGaAsP, monolithic InP, and others^{3,4}. The InP/GaAs material system is the dominant system used for long-wavelength VCSELs; an alternate material system that can reach these wavelengths are the III-nitrides whose emissions span from 200 nm for AlN to 1900 nm for InN.

While InP/GaAs-based VCSELs benefit from simpler manufacturing processes due to lattice matching between the active region and substrate, they suffer from lower thermal stability.⁵ The bandgap energy of the active region, at 0.76 eV, is only 0.59 eV less than that of the lattice matched substrate InP, at 1.35 eV. This small band-offset leads to significant carrier overflow at the high temperatures of operation. This requires significant investments of money and space for cooling systems when using these devices, and limits the ability to utilize one of VCSEL's main features, high-powered 2-dimensional arrays⁴. Alternatively, the III-Nitride system has a far superior band offset, and therefore improved thermal stability. The large band-offset originates from the large band gap energy of GaN (3.4 eV) relative to that of InN (0.7 eV), making it a promising candidate for addressing the rising power and thermal management requirements of modern data centers. However, the large lattice mismatch and disparate growth conditions between GaN and InN have made it difficult to manufacture functioning devices⁶. The use of high indium content quantum dots (QDs) has been shown to be a viable way to get long-wavelength emission, circumventing the lattice mismatch by relaxing the strain through island growth and growing under lower temperatures and higher nitrogen content⁷. Besides benefiting from the superior thermal stability of being a III-N material, the use of InN QDs as described herein provides an additional benefit for laser operation as the reduced dimensionality of the active layer increases the material gain.

For applications requiring higher laser powers such as free-space optics or radar, VCSEL arrays manufactured using GaN are favorable relative to in-plane lasers due to ease of fabrication, low costs and favorable lifetimes (due to superior thermal stability) relative to GaAs/InP VCSELs. In VCSEL arrays, thermal crosstalk becomes an important issue; individual VCSELs in the array generate heat that can heat up nearby devices⁸. The temperature increase from thermal crosstalk limits how close GaAs/InP VCSELs can be on an array which ultimately limits their high power potential; GaN VCSELs could be placed closer together to create high power arrays.

Another example application includes utilizing GaN VCSELs in optical coherence tomography (OCT) and 3D macroscopic imaging. In these applications, long-wavelength GaAs/InP VCSELs provide unparalleled beam control and tunability over in-plane lasers. However, the best performing GaAs/InP VCSELs for imaging are optically pumped due to the resistive heating and lower gain associated with electrically-pumped devices⁹. Optical pumping limits wall-plug efficiency and increases the complexity and cost of imaging devices, since two lasers are required for one output imaging beam. GaN VCSELs utilizing InN or high indium content QDs as described herein could greatly simplify the device manufacturing process by being electrically pumped while at the same time minimizing thermal issues and maintaining high gain due to the QD's confinement effects discussed earlier.

### H. REFERENCES FOR SECTION II

Time following references are incorporated by reference herein.

1. Tatum, J. A. Evolution of VCSELs. in Vertical-Cavity Surface-Emitting Lasers XVIII 9001, 90010C (International Society for Optics and Photonics, 2014).

2. Wang, Z. et al. Cubic meter volume optical coherence tomography. Optica 3, 1496-1503 (2016).

3. Hofmann, W. et al. 22-Gb/s Long Wavelength VCSELs. Opt. Express 17, 17547 (2009).

4. Amann, M. & Hofmann, W. InP-Based Long-Wavelength VCSELs and VCSEL Arrays. IEEE J. Sel. Top. Quantum Electron. 15, 861-868 (2009).

5. Liu, A., Wolf, P., Lott, J. A. & Bimberg, D. Vertical-cavity surface-emitting lasers for data communication and sensing. Photonics Res. 7, 121 (2019).

6. Yam, F. K. & Hassan, Z. InGaN: An overview of the growth kinetics, physical properties and emission mechanisms. Superlattices Microstruct. 43, 1-23 (2008).

7. Soto Rodriguez, P. E. D., Gómez, V. J., Kumar, P., Calleja, E. & Nötzel, R. Near-infrared InN quantum dots on high-In composition InGaN. Appl. Phys. Lett. 102, 131909 (2013).

8. Sato, K. & Murakami, M. Experimental investigation of thermal crosstalk in a distributed feedback laser array. IEEE Photonics Technol. Lett. 3, 501-503 (1991).

9. Jayaraman, V., Cole. G. D., Robertson, M., Uddin, A. & Cable, A. High-sweep-rate 1310 nm MEMS-VCSEL with 150 nm continuous tuning range. Electron. Lett. 48, 867-869 (2012).

10. Zhang, J., Gao, Y., Zhou, L., Gil, Y.-U. & Kim, K.-M. Surface hole gas enabled transparent deep ultraviolet light-emitting diode. Semicond. Sci. Technol. 33, 07LT01 (2018).

III: Transparent Vertical Cavity Surface Emitting Laser

While virtual reality applications are already gaining market traction, truly augmented and mixed reality applications based on transparent displays remain an ultimate end-goal for overlaying information without disconnecting the user from the surrounding environment. Although some products have been market tested [1]-[3], a number of key challenges remain, including delivery of full-color images, energy consumption, and pixel size. The latter detrimentally affects both image resolution and display transparency [4]. To date, development of wearable AR/MR displays has leveraged either edge-emitting lasers, or mini-LEDs (approximately 100 μm to a side). Mini-LEDs are attractive, as they leverage existing LED growth and fabrication infrastructure. However, the Lambertian emission profile of these devices results in a low system efficiency, significant pixel-to-pixel crosstalk, and a maximum display transparency of 50% when Light Emitting Diodes (LEDs) are used as individual pixels. Research is underway to reduce the size of individual LEDs to <10 μm to a side, although the external quantum efficiency of such devices drops off due to non-radiative recombination at the device edges [5]. Alternatively, edge emitting lasers provide a more directional output than mini-LEDs, while significantly complicating the system design, requiring beam steering and focusing optics. This architecture also raises concerns over eye-safety since edge emitting lasers deliver more power than required for near-eye applications.

What is needed, then, is a laser system that is safer and more efficient than conventional light sources used in transparent displays. Embodiments of the present invention satisfy this need.

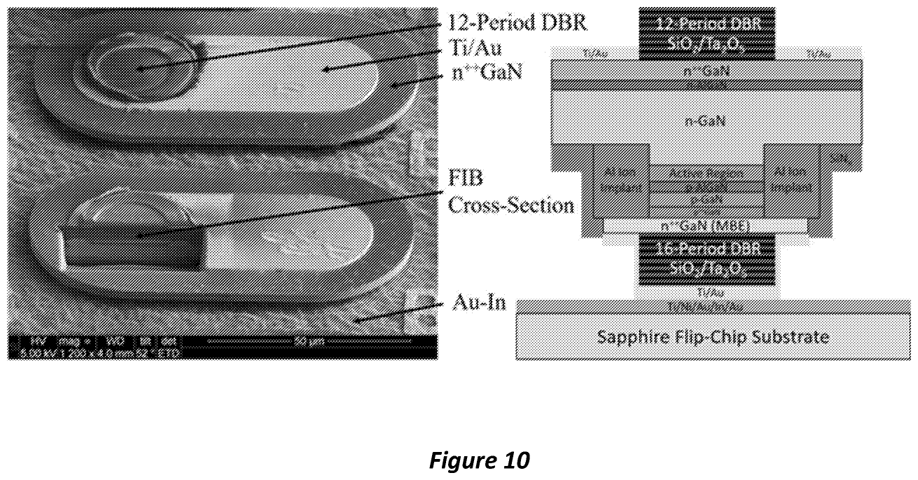

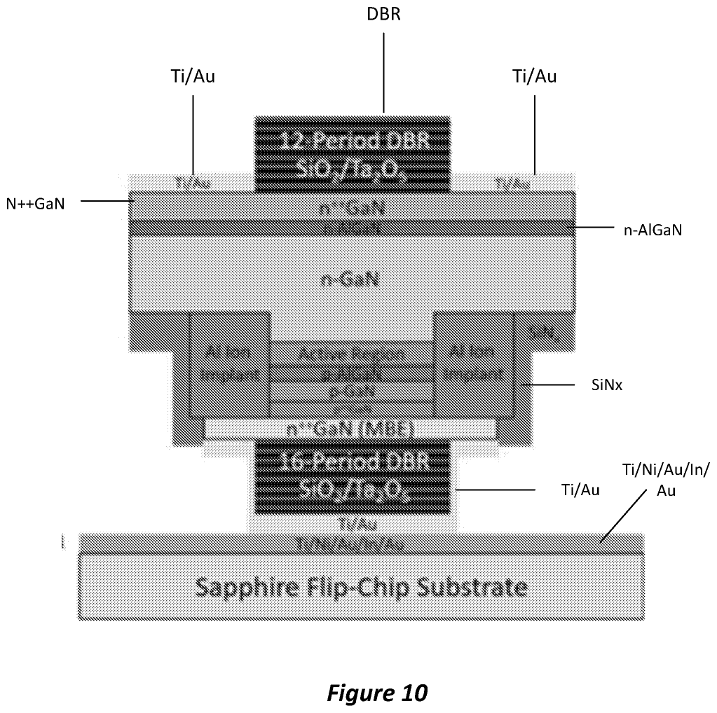

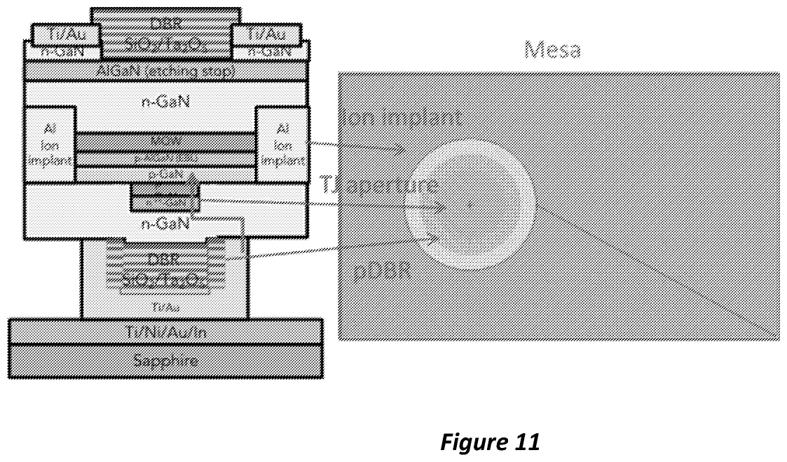

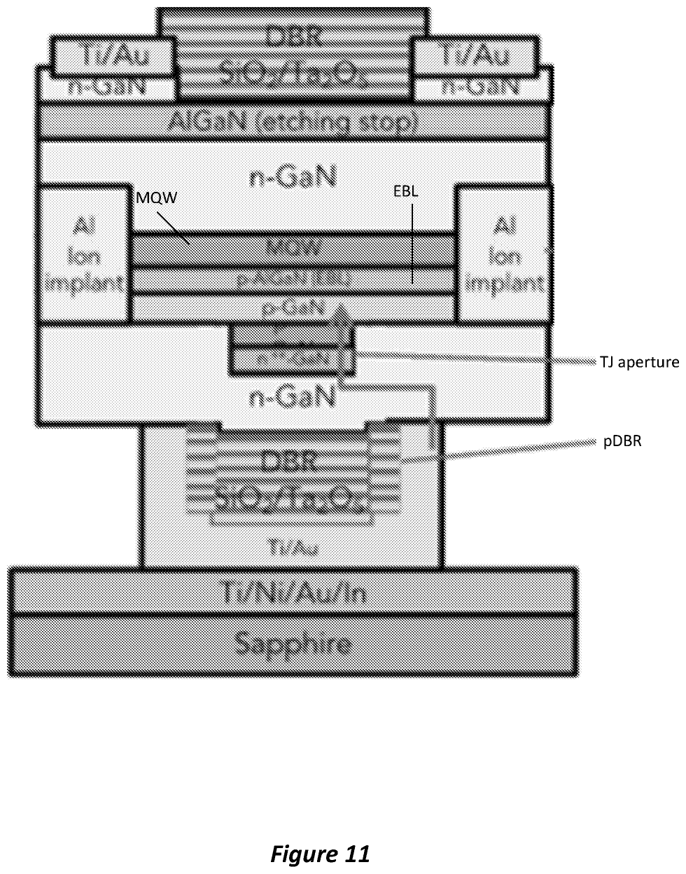

FIGS. 10 and 11 illustrate VCSELs capable of continuous wave (CW) operation [8], [10]. For the device in FIG. 10, current confinement in the structure is achieved using Al ion implantation. Epitaxial growth is achieved by MOCVD off of an m-plane bulk GaN substrate. The active region comprises two 14 nm thick InGaN quantum wells. To minimize absorption in the p-type and p-contact layers, and to maximize current spreading, a tunnel-junction contact is incorporated in lieu of a more common ITO contact [9]. The tunnel junction provides for increased device transparency, although transparent conductive oxides may be used without significantly affecting overall transparency. The tunnel junction is grown by molecular beam epitaxy (MBE) on a p-type GaN layer and electrical contact to the MBE layer is made via a Ti/Au metal contact. However, as demonstrated in the device in FIG. 11, the tunnel junction may also be formed entirely through MOCVD growth. The optical cavity is formed by removing the bulk substrate via a photoelectrochemical undercut etch (PEC) of an epitaxially grown InGaN sacrificial layer and depositing high-reflectivity dielectric distributed Bragg reflector (DBR) stacks. Alternative methods to remove the substrate include laser lift-off mechanical polishing, plasma- or ion-based dry-etching, or a combination of these techniques. The device in FIG. 10 is flip-chip bonded to a coated sapphire substrate using In/Au solid-liquid interdiffusion bonding. This bonding, in combination with the thicker cavity and careful management of roughness at each interface, contributes to the robust lasing capability in CW testing.

The device in FIG. 11 leverages a buried tunnel junction (BJT) for current confinement, with ion implantation used as an additional mechanism to reduce surface leakage across the active region at the dry-etched mesa sidewall. The tunnel junction contact to the p-GaN is first etched, then buried via a regrowth of moderately doped n-type GaN—the doping is sufficiently high to achieve an ohmic contact to the metal pad, but low enough such that current flow between the regrown layer and the p-type GaN at the etch interface is suppressed. The device in FIG. 11 is otherwise similar to the one shown in FIG. 10.

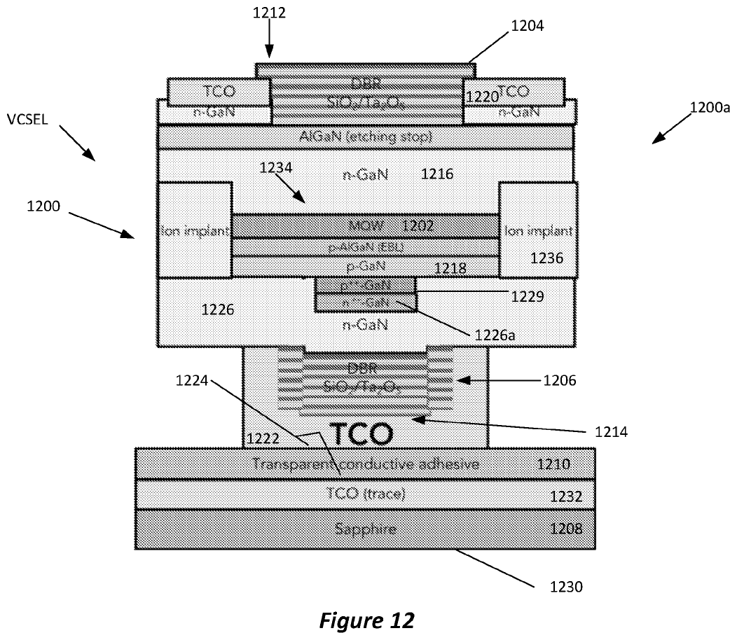

FIG. 12 illustrates a device 1200 according to one or more embodiments of the present invention. wherein all layers of the VCSEL are transparent to visible wavelengths except for an emitting layer 1202 (e.g., multi quantum wells, MQW) and cavity mirrors 1204, 1206 defining a lasing cavity of the VCSEL. FIG. 12 further illustrates a submount 1208 and a bonding material 1210 bonding the submount to the VCSEL, wherein the submount and the bonding material are transparent to the visible wavelengths of the electromagnetic radiation emitted by the emitting layer.

The VCSEL may emit electromagnetic radiation (e.g., light) through a first surface 1212 that is not bonded to the submount and/or through a second surface 1214 that is bonded to the submount.

FIG. 12 illustrates an example wherein the VCSEL includes an epitaxial structure including a III-nitride active region 1202 between a first III-nitride n-type layer 1216 and a III-nitride p-type layer 1218; the first mirror 1204 and the second mirror 1206 on opposite sides of the epitaxial structure; a first electrical contact 1220 to or for the n-type layer 1216, the first electrical contact comprising a first transparent conductive oxide (TCO); and a second electrical contact 1222 to or for the p-type layer 1218, the second electrical contact comprising a second TCO. At least a portion of the epitaxial structure is between the first contact 1220 and the second contact 1222. Electromagnetic radiation is emitted from the active region 1202 in response to a voltage applied between the first electrical contact 1220 and the second electrical contact 1222. The electromagnetic radiation is outputted from the VCSEL through the first mirror 1204 or the second mirror 1206, and a surface 1224 on which the VCSEL is mounted is visible through the first electrical contact 1220, the second electrical contact 1222, and the portion of epitaxial structure between the first contact and the second contact.

The bonding material 1210 and the submount 1208 are transparent or include portions that are transparent to visible wavelengths such that a surface 1230 on which the submount is mounted is visible through the first contact 1220, the second contact 1222, the submount or portions of the submount, and the bonding material.

FIG. 12 shows the first contact 1220 is positioned around a perimeter of the first mirror or includes sections on opposite sides of the first mirror 1204; and the second contact 1222 is on all exposed surfaces of the second mirror 1206. In the example of FIG. 12, the second mirror 1206 is embedded in the second contact 1222.

FIG. 12 illustrates the epitaxial structure further includes a second III-nitride n-type layer 1226 forming a tunnel junction 1228 with the III-nitride p-type layer, and the second electrical contact 1222 forming an electrical contact to the tunnel junction 1228 and second III-nitride n-type layer 1226.

FIG. 12 illustrates an example wherein the device 1200 fluffier includes a third transparent conductive oxide layer 1232 between the bonding material 1210 and the submount 1208, wherein the third transparent conductive oxide includes electrical traces for electrically contacting with the VCSEL and/or comprises electrically conductive paths used in a display attached to or comprising the VCSEL.

FIG. 12 further illustrates the device includes current aperture 1234 defined in the epitaxial layers, the current aperture defined using ion implanted material 1236, a dielectric or air-gap aperture, a buried tunnel junction, or a combination thereof.

The epitaxial layers of the device are grown by MOCVD on a non-polar or semi-polar oriented GaN substrate. A c-plane oriented substrate may also be used, although the polarization of the final device will be random. Sapphire, SiC, and silicon substrates can be used as the base for epitaxial growth, although considerations must be made to remove the substrate (sapphire, SiC, or Si), incorporate it into the cavity (sapphire), or leverage an epitaxial Distributed Bragg Reflector (DBR) in order to create a transparent device. The active region, electron blocking layer (EBL), n-GaN and p-GaN regions are specific to the desired output wavelength of the device.

However, the concepts described herein can apply equally to any III-N VCSELs. Current confinement is achieved via a buried tunnel junction (BTJ) in combination with ion implantation. However, aperturing by a dielectric or air-gap aperture, by ion implantation without a BTJ, or by a BTJ without the ion implantation can also work. While the device shown in FIG. 12 utilizes dielectric DBRs to form the cavity. epitaxial DBRs may also be used. In particular, epitaxial DBRs may improve overall transparency as the wavelength stop-band of these mirrors is narrower.

The top-side contact in the device of FIG. 12 is a transparent conductor such as (but not limited to) indium tin oxide (ITO) or zinc oxide (ZnO), instead of the Ti/Au contact shown in FIGS. 10 and 11. In addition, the bottom contact/pad in FIG. 12 is also a transparent conductor such as ZnO. An alternative design has both p-side and n-side contacts on the same side of the device. Flip-chip bonding onto the package submount (e.g. sapphire, glass, polymer) can be accomplished using transparent, conducting adhesives—often a polymer matrix imbedded or embedded with metal particles that form electrical contact as force is applied to the bonding layer. The traces on the submount are also fabricated from a transparent conductor. The submount itself can be continuous and transparent or incorporate vias for light transmission. The submount can be rigid (e.g. sapphire) or flexible.

A. Display

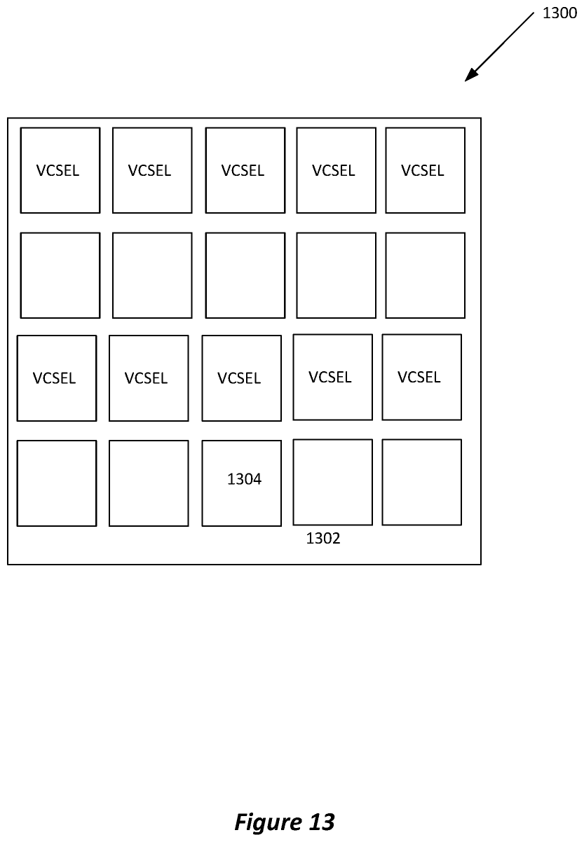

FIG. 13 illustrates a display 1300 comprising an array of the VCSELs, wherein the surface 1302 on which the VCSELs are mounted is a display screen electronically displaying text and/or graphics that is readable or viewable by naked eye (or with glasses or contact lenses) through the first contact 1220, the second contact 1222, the portion of epitaxial material between the first contact 1220 and second contact 1222, the bonding material 1210, and/or the submount 1208. Each of the VCSELs comprise a pixel 1304 in the display, each of the VCSELs are on or above a surface 1302, and more than 50% of the intensity of each of red, green, and blue light emitted from the surface is transmitted through the combined thickness of the first contact, the portion of the epitaxial structure, and the second contact. Each of the VCSELs in the display can emit at least one of red, blue, or green wavelengths.

In one or more examples, more than 50% of the intensity of each of red, green, and blue light emitted from the surface 1302 is transmitted through the submount, the bonding material (and optionally also the third transparent conductive oxide), the second contact, the portion of the epitaxial structure, and the first contact.

In one or more examples, the display comprises a virtual reality or augmented reality or mixed reality display.

B. Device Embodiments

As illustrated and described herein, the device can be embodied in many ways, including but not limited to, the following (referring also to FIGS. 12 and 13).

1. A device, comprising a VCSEL wherein all layers of the VCSEL are transparent (e.g., at least 50% transmittivity or transparency) to visible wavelengths except for: an emitting layer 1202, and cavity mirrors 1204, 1206 defining a lasing cavity of the VCSEL.

2. The device of embodiment 1, further comprising a submount 1208 and a bonding material 1210 bonding the submount to the VCSEL, wherein the submount and the bonding material are transparent (e.g., at least 50% transmittivity or transparency) to the visible wavelengths.

3. The device of embodiment 2, wherein the VCSEL emits light through a surface 1212 that is not bonded to the submount.

4. The device of embodiment 2, wherein the VCSEL emits light through a surface 1224 that is bonded to the submount 1208.

5. The device of embodiment 1, wherein the cavity mirrors are dielectric mirrors.

6. The device of embodiment 1, wherein the cavity mirrors are epitaxial mirrors, dielectric mirrors, or a combination thereof.

7. A device, comprising: a VCSEL, including an epitaxial structure 1200a including a III-nitride active region 1202 between a first III-nitride n-type layer 1216 and a III-nitride p-type layer 1218; a first mirror 1204 and a second mirror 1206 on opposite sides of the epitaxial structure 1200a; a first contact 1220 on or to (e.g., forming an electrical contact to) the n-type layer 1216, the first contact comprising a first transparent conductive oxide (TCO); and a second contact 1222 to the p-type layer 1218 (e.g., forming an electrical contact to the p-type layer 1218), the second contact 1222 comprising a second transparent conductive oxide (TCO); and wherein at least a portion of the epitaxial structure 1200a is between the first contact 1220 and the second contact 1222, electromagnetic radiation is emitted from the active region 1202 in response to a voltage applied between the first contact 1220 and the second contact 1222, the electromagnetic radiation is outputted from the VCSEL through the first mirror 1204 or the second mirror 1206, and a surface 1214 on which the VCSEL is mounted is visible through the first contact 1220, the second contact 1222, and the portion of epitaxial structure 1200a between the first contact 1220 and the second contact 1222.

8. The device of embodiment 7, wherein the first mirror 1204 and the second mirror 1206 each comprise a distributed bragg reflector comprising epitaxial and/or dielectric material.

9. The device of embodiments 7 or 8, wherein the first contact 1220 is positioned around a perimeter of the first mirror 1204 or includes sections on opposite sides of the first mirror; and the second contact 1222 is on all exposed surfaces 1214 of the second mirror 1206.

10. The device of embodiments 7, 8, or 9, wherein the second mirror 1206 is embedded in the second contact 1222.

11. The device of any of the embodiments 7-10, wherein the first and second transparent conductive oxides each independently comprise indium tin oxide, or zinc and oxygen (e.g., zinc oxide).

12. The device of any of the embodiments 7-11, further comprising a second III-nitride n-type layer 1226, 1226a forming a tunnel junction 1229 with the III-nitride p-type layer 1218, and the second contact 1222 forming a contact (e.g, electrical contact) to the tunnel junction 1229.

13. The device of any of the embodiments 7-12, further comprising a submount and 1208 a bonding material 1210 bonding the submount 1208 to the VCSEL, wherein the submount 1208 and the bonding material 1210 are transparent or include portions that are transparent to visible wavelengths such that a surface 1230 on which the submount is mounted is visible through the first contact 1220, the second contact 1222, the submount 1208 or portions of the submount, and the bonding material 1210.

14. The device of embodiment 13, wherein the bonding material 1210 bonds the second contact 1222 to the submount 1208.

15. The device of embodiments 13 or 14, further comprising a third transparent conductive oxide 1232 between the bonding material 1210 and the submount 1208, wherein the third transparent conductive oxide includes electrical traces for electrically contacting with the VCSEL and/or comprises electrically conductive paths used in a display attached to or comprising the VCSEL.

16. The device of any of the embodiments 13-15, wherein the bonding material 1210 comprises a conductive adhesive.

17. The device of embodiment 16, wherein the bonding material 1210 includes metal particles embedded in a polymer matrix.

18. The device of any of the embodiments 13-17, wherein the submount 1208 comprises sapphire, glass, or polymer.

19. The device of any of the embodiments 7-18, further comprising a current aperture 1234 defined in the epitaxial layers 1206, 1202, 1218 the current aperture 1234 defined using ion implanted material 1236, a dielectric or air-gap aperture, a buried tunnel junction (BTJ), or a combination thereof.

20. A display 1300 comprising an array of the VCSELs of any of the embodiments 1-19, wherein the surface 1302 on which the VCSELs are mounted is a display screen electronically displaying text and/or graphics that is readable or viewable by naked eye (e.g., using the visible wavelengths) through the first contact 1220, the second contact 1222, the portion of epitaxial material 1200a between the first contact and second contact 1222, the bonding material 1210, and/or the submount 1208.

21. A display 1300 comprising an array of the VCSELs of any of the embodiments 1-19, wherein each of the VCSELs comprise a pixel 1304 in the display, each of the VCSELs are on or above a surface 1302, and more than 50% (e.g., 50%-100% or 50%-99%) of the intensity of each of red, green, and blue light (e.g., comprising the visible wavelengths) emitted from the surface 1302 is transmitted through the combined thickness of the first contact 1220, the portion of the epitaxial structure 1200a, and the second contact 1222.

22. A display 1300 comprising an array of the VCSELs of any of the embodiments 1-19, wherein each of the VCSELs comprise a pixel 1304 in the display, each of the VCSELs are on or above a surface 1302, and more than 50% (e.g., 50%-100% or 50%-99%) of the intensity of each of red, green, and blue light (e.g., comprising the visible wavelengths) emitted from the surface 1302 is transmitted through the submount 1208, the bonding material 1210 (and optionally also the third transparent conductive oxide 1232), the second contact 1222, the portion of the epitaxial structure 1200, and the first contact 1220.

23. The display of embodiments 20-22, wherein the display 1300 comprises a virtual reality or augmented reality display.

24. The display or VCSEL of any of the preceding examples, wherein the layers transparent to visible wavelengths (e.g., blue, green, red) comprises all layers of the VCSEL except for the emitting layer 1202, and cavity mirrors 1204, 1206, submount 1208, the bonding material 1210, the first contact 1220, and the second contact 1222 comprising thicknesses (e.g., sufficiently thin) and material having a transmittivity or transparency for visible wavelengths in a range of 50%-100%, or between 40%-90%.

25. In one or more examples, visible wavelengths comprise but are not limited to, one or more wavelengths in a range of 380 nm-740 nm (nanometers).

C. Process Steps

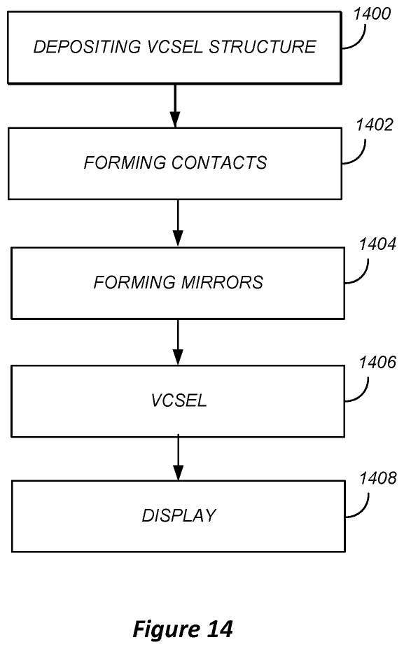

FIG. 14 is a flowchart illustrating a method of making a device.

Block 1400 represents growing a VCSEL epitaxial structure including a III-nitride active region between a first III-nitride n-type layer and a III-nitride p-type layer.

Block 1402 represents forming contacts to the VCSEL. In one or more examples, the step comprises forming a first contact to the n-type layer, the first contact comprising a first transparent conductive oxide; and a second contact to the p-type layer, the second contact comprising a second transparent conductive oxide, wherein at least a portion of the epitaxial structure is between the first contact and the second contact.

Block 1404 represents forming mirrors.

Block 1406 represents the end result, a VCSEL, e.g., as illustrated in FIG. 12 or described in the examples of section B. Electromagnetic radiation is emitted from the active region in response to a voltage applied between the first contact and the second contact, the electromagnetic radiation is outputted from the VCSEL through the first mirror or the second mirror, and a surface on which the VCSEL is mounted is visible through the first contact, the second contact, and the portion of epitaxial structure between the first contact and the second contact.

Block 1408 represents optionally disposing a plurality of the VCSELs in a display.

### Advantages and Improvements for Section III

While virtual reality applications are already gaining market traction, truly augmented and mixed reality applications based on transparent displays remain an ultimate end-goal for overlaying information without disconnecting the user from the surrounding environment. Although some products have been market tested [1]-[3], a number of key challenges remain, including delivery of full-color images, energy consumption, and pixel size. The latter detrimentally affects both image resolution and display transparency [4]. To date, development of wearable AR/MR displays has leveraged either edge-emitting lasers, or mini-LEDs (approximately 100 μm to a side). Mini-LEDs are attractive, as they leverage existing LED growth and fabrication infrastructure. However, the Lambertian emission profile of these devices results in a low system efficiency, significant pixel-to-pixel crosstalk, and a maximum display transparency of 50% when LEDs are used as individual pixels. Research is underway to reduce the size of individual LEDs to <10 μm to a side, although the external quantum efficiency of such devices drops off due to non-radiative recombination at the device edges [5]. Alternatively, edge emitting lasers provide a more directional output than mini-LEDs, while significantly complicating the system design, requiring beam steering and focusing optics. This architecture also raises concerns over eye-safety since edge emitting lasers deliver more power than required for near-eye applications.

In contrast, VCSELs provide highly-directional emission in a compact form-factor—≤100 μm in diameter—with light output ranging from 0.2-1 mW for single devices. Light is emitted perpendicular to the plane of the device for simplified packaging, and this orientation may simplify beam steering via MEMS or tunable optics [6]. For example, VCSELs have recently been mass-deployed in three dimensional (3D) scanning applications such as the facial recognition in a smartphone [7]. The low threshold currents of VCSELs result in lower power consumption and increased battery lifetimes. Furthermore, nonpolar and semipolar VCSELs have been shown to have a 100% polarization ratio, enabling true polarization-locked displays without requiring two separate in-line polarizers and further increasing system efficiency.

A fully transparent VCSEL as described herein can further improve the optical efficiency of these types of displays, while still providing the benefits of a traditional VCSEL in terms of packaging and polarization. In conjunction with transparent electrical traces, a transparent VCSEL can also open up the design window for see-through displays by removing restrictions on where the devices can be placed.

### REFERENCES FOR SECTION III

The following references are incorporated by reference herein

[1] “RideOn—The AR Lifestyle.” [Online]. Available: https://www.rideonvision.com/new/ski-goggle.php#ski-goggle. [Accessed: 12 Sep. 2018].

[2] “Transparent LED Panel, Glass LED Display Case, Transparent LED Screen—AuroLED TECH.” [Online]. Available: http://www.auroled.com/gallery/transparent_display_cases/?gclid=EAIaIQobChMIi6esv_S23QIVT2F-Ch2edw7AEAMYASAAEgLWj_D_BwE. [Accessed: 12 Sep. 2018].

[3] “Transparent OLED Displays|Planar.” [Online]. Available: http://www.planar.com/innovations/transparent-oled/. [Accessed: 12 Sep. 2018].

[4] R. Azuma, Y. Baillot, R. Behringer, S. Feiner, S. Julier, and B. MacIntyre, “Recent Advances in Augmented Reality.” 2001.

[5] D. Hwang, A. Mughal, C. D. Pynn, S. Nakamura, and S. P. DenBaars, “Sustained high external quantum efficiency in ultrasmall blue III-nitride micro-LEDs,” Appl. Phys. Express, vol. 10, no. 3, p. 032101, March 2017.

[6] J. Kramer and D. Henderson, “Micro Beam Steering: Precision micro beam-steering systems simplify move to handheld instruments—Laser Focus World,” 2015. [Online]. Available: https://www.laserfocusworld.com/articles/print/volume-51/issue-07/feature/micro-beam-steering-precision-micro-beam-steering-systems-simplify-move-to-handheld-instruments.html. [Accessed: 12 Sep. 2018].

[7] A. Extance, “Faces light up over VCSEL prospects,” SPIE Newsroom, April 2018.

[8] C. A. Forman et al., “Continuous-wave operation of m-plane GaN-based vertical-cavity surface-emitting lasers with a tunnel junction intracavity contact,” Appl. Phys. Lett., vol. 112, no. 11, p. 111106, March 2018.

[9] A. J. Mughal et al., “Polarization-enhanced InGaN/GaN-based hybrid tunnel junction contacts to GaN p-n diodes and InGaN LEDs,” Appl. Phys. Express, vol. 10, no. 12, p. 121006, December 2017.

[10] International Patent Application No. PCT/US18/53982 entitled III-NITRIDE SURFACE-EMITTING LASER AND METHOD OF FABRICATION.

[11] U.S. Pat. No. 7,781,789.

[12] U.S. Pat. No. 8,368,109.

IV. Nomenclature

GaN and its ternary and quaternary compounds incorporating aluminum and indium (AlGaN, InGaN, AlInGaN) are commonly referred to using the terms (Al,Ga,In)N, III-nitride, III-N, Group III-nitride, nitride, Al_{(1-x-y)}In_{y}GaₓN where 0<x<1 and 0<y<1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials. Boron (B) may also be included.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semi-polar planes of the crystal. The term “semi-polar plane” (also referred to as “semipolar plane”) can be used to refer to any plane that cannot be classified as c-plane, a-plane, or m-plane. In crystallographic terms, a semi-polar plane may include any plane that has at least two nonzero h, i, or k Miller indices and a nonzero l Miller index.

Some commonly observed examples of semi-polar planes include the (11-22), (10-11), and (10-13) planes. Other examples of semi-polar planes in the wurtzite crystal structure include, but are not limited to, (10-12), (20-21), and (10-14). The nitride crystal's polarization vector lies neither within such planes or normal to such planes, but rather lies at some angle inclined relative to the plane's surface normal. For example, the (10-11) and (10-13) planes are at 62.98° and 32.06° to the c-plane, respectively.

The Gallium or Ga face of GaN is the c⁺ or (0001) plane, and the Nitrogen or N-face of GaN or a III-nitride layer is the c⁻ or (000-1) plane.

The prefix n- (e.g., n-GaN) represents n-type, the prefix n⁺⁺—(e.g., n++-GaN) represents higher n-type dopant concentration, the prefix p- (e.g., p-GaN) represents p-type, the prefix p⁺⁺—(e.g., p++-GaN) represents higher p-type dopant concentration.

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A device, comprising:
a III-Nitride based Vertical Cavity Surface Emitting Laser (VCSEL), comprising:
a III-Nitride active region between a p-type III-Nitride layer and an n-type III-Nitride layer; and
a curved mirror on or above the p-type III-Nitride layer such that the p-type III-Nitride layer is between the III-Nitride active region and the curved mirror.

2. The device of claim 1, wherein the VCSEL further comprises:
one or more tunnel junction layers on the p-type III-Nitride layer, wherein the curved mirror is formed on or above the tunnel-junction layers such that the tunnel-junction layers are between the curved mirror and the p-type III-Nitride layer.

3. The device of claim 2, wherein the VCSEL further comprises:
a second n-type III-Nitride region on or above the tunnel-junction layers, wherein the the curved mirror includes the second n-type III-Nitride region and second the n-type III-Nitride region has a curvature forming the curved mirror.

4. The device of claim 3, wherein the second n-type III-Nitride region has an etched surface having the curvature.

5. The device of claim 4, wherein the second n-type III-Nitride region comprises n-type gallium nitride or unintentionally doped gallium nitride.

6. The device of claim 1, wherein:
the VCSEL further comprises a flat distributed bragg reflector (DBR) mirror,
the curved mirror comprises a curved DBR mirror,
the III-Nitride active region is between the flat DBR mirror and the curved DBR mirror, and
the flat DBR mirror and the curved DBR mirror define a cavity of the VCSEL.

7. The device of the claim 6, wherein a total cavity length of the cavity is more than 8 micrometers.

8. The device of claim 6, wherein more than 50% of the VCSEL's cavity is composed of, comprises, or consists essentially of epitaxially grown GaN, unintentionally doped (UID) GaN or n-type GaN.

9. The device of the claim 1, wherein all of the III-Nitride layers of the VCSEL are grown epitaxially by metal organic chemical vapor deposition (MOCVD).

10. The device of any of claim 1, wherein:
the VCSEL further comprises a flat III-nitride layer and a first Distributed Bragg Reflector (DBR) on the flat III-nitride layer,
the active region is between the flat III-nitride layer and the curved mirror,
the curved mirror includes a second Distributed Bragg Reflector (DBR), and
a distance between the second DBR and the active region is shorter than the distance between first DBR and the active region.

11. The device of claim 1, wherein:
the VCSEL further comprises an unintentionally doped gallium nitride (UID GaN) layer on the n-type III-Nitride layer, wherein the UID GaN is thick (thicker than the n-type III-Nitride layer),
the n-type III-Nitride layer comprises n-type gallium nitride (n-GaN),
the UID GaN is etched to expose a surface of the n-GaN, and
a metal contact or Ohmic contact material is deposited on the exposed surface of the n-GaN.

12. A method of fabricating the VCSEL, comprising:
growing the VCSEL structure on a gallium nitride (GaN) substrate; and
removing the GaN substrate so that the GaN substrate can be re-used more than 3 times, wherein the VCSEL structure comprises a III-Nitride active region between a p-type III-Nitride layer and an n-type III-Nitride layer; and the VCSEL comprises a curved mirror on or above the p-type III-Nitride layer such that the p-type III-Nitride layer is between the III-Nitride active region and the curved mirror.

13. A device, comprising:
a III-Nitride based Vertical Cavity Surface Emitting Laser (VCSEL), comprising a curved mirror formed on or in a Transparent Oxide (TO) material.

14. The device of claim 13, wherein the transparent Oxide (TO) material comprises ZnO, Ga₂O₃, or Al₂O₃.

15. The device of claim 13, wherein the VCSEL further comprises:
a III-Nitride active region between a p-type III-Nitride layer and an n-type III-Nitride layer; and
the transparent Oxide (TO) material on or above the p-type III-Nitride layer such that the p-type III-Nitride layer is between the III-Nitride active region and the Transparent Oxide (TO) material having a curved surface forming the curved mirror.

16. The device of claim 15, further comprising:
a III-Nitride tunnel junction on the p-type III-Nitride layer, wherein the transparent Oxide (TO) material is grown on or above the IIII-Nitride tunnel junction such that the III-Nitride tunnel junction is between the curved mirror and the p-type III-Nitride layer.

17. The device of claim 13, wherein:
the VCSEL further comprises a flat DBR mirror,
the curved mirror comprises a curved DBR mirror,
the flat DBR mirror and the curved DBR mirror define a cavity of the VCSEL.

18. The device of claim 17, wherein a total cavity length of the VCSEL's cavity is more than 8 micrometers.

19. The device of any claim 13, wherein all of the III-Nitride layers of the VCSEL are grown epitaxially by metal organic chemical vapor deposition (MOCVD).

20. The device of claim 13, wherein a thickness of the transparent oxide material is more than 5 micrometers.

21.-68. (canceled)
